(19) United States
(12) Patent Application Publication
(10) Pub. No.: US 2026/0363070 A1
(43) Pub. Date: Nov. 12, 2026

(54) POWER ELECTRONICS COMPONENT WITH COOLING AND A POWER CONVERTER

(71) Applicant: TRUMPF Hüttinger GmbH + Co. KG, Freiburg (DE)

(72) Inventors: Guido Dieter Hodapp, Emmendingen (DE); Thilo Vethake, Roosevelt, NJ (US); Aguiar Wagner, Jackson, NJ (US); Vajpey Divya, Somerset, NJ (US); Craig Denham, Millbury, MA (US); Reza Razavi, Monrovia, CA (US)

(21) Appl. No.: 19/672,813

(22) Filed: May 11, 2026

Related U.S. Application Data
(63) Continuation of application No. PCT/EP2024/082606, filed on Nov. 15, 2024.

(30) Foreign Application Priority Data
Nov. 15, 2023 (DE) 10 2023 131 877.2

(51) Int. Cl. H10W 40/20; H10W 40/47

(52) U.S. Cl. CPC H10W 40/242; H10W 40/47

(57) ABSTRACT

A power electronics component, including a first substrate with upper and lower metallization layers, and a semiconductor assembly mounted on the first substrate. The upper metallization layer of the first substrate faces the semiconductor assembly. The power electronics component includes a second substrate with upper and lower metallization layers. The semiconductor assembly has a second connection to a second region of the lower metallization layer of the second substrate. The lower metallization layer of the second substrate faces the semiconductor assembly. The power electronics component includes a first heat sink connected to the lower metallization layer of the first substrate, which faces away from the semiconductor assembly, the first heat sink having a first cooling channel, and a second heat sink connected to the upper metallization layer of the second substrate, which faces away from the semiconductor assembly, the second heat sink having a second cooling channel.

### CROSS REFERENCE TO RELATED APPLICATIONS

This application is a continuation of International Application No. PCT/EP2024/082606 (WO 2025/104319 A1), filed on Nov. 15, 2024, and claims benefit to German Patent Application No. DE 10 2023 131 877.2, filed on Nov. 15, 2023. The aforementioned applications are hereby incorporated by reference herein.

### FIELD

The invention relates to a power electronics component with cooling, a method for joining a power electronics component, and to an electrical power converter for an industrial process assembly.

### BACKGROUND

There are particular challenges for cooling, in particular in the field of electrical power conversion for special power-intensive and instability-prone industrial processes, such as plasma excitation, plasma coating processes, gas laser excitation, particle accelerators, charging and discharging systems for large batteries, such as flow batteries, melting of solids, heating and/or gasification of liquids by, for example, microwave energy or induction heating or plasma torches. This can be a process for generating radiation, e.g., microwave radiation, X-ray radiation or particle accelerators. A feature common to all of these processes is that they are designed to generate and accelerate charged atomic or subatomic particles in a gas and/or plasma environment or liquid. Another feature common to all of these processes is that they have a high power consumption which is in the range of 1 kW or more, in particular 10 kW or more, preferably 100 kW or more. In this process, frequencies ≥20 kHz, preferably ≥200 kHz, and in particular ≥2 MHz, are generated for the aforementioned power range, either internally or for external applications. Many of these processes also have a very high requirement for the stability of the power supply because the processes are highly complex, such as semiconductor manufacturing using plasma processes and/or heating by electromagnetic fields. Typically, power is converted from a mains frequency, which is in the range of approximately 50 Hz to 60 Hz, to different frequencies that can fall within the aforesaid range. Conversion to direct-current power, also called DC power, is also provided. Even when converting to direct current power, the power signal is often internally generated at a frequency in the aforementioned range, which is then rectified again according to the requirements for voltage, current, and power. Converting electrical power to other frequencies requires a multitude of electronic components and assemblies, in particular power semiconductor components such as transistors or diodes, in particular PIN diodes, e.g., for switching HF power between different paths, or a combination of transistor and diode designed for currents ≥10 A and voltages ≥400 V. These electronic components and assemblies generate waste heat during operation. The waste heat often occurs over a very limited area of just a few mm², e.g., ≤8 mm². It is a particular challenge to dissipate this waste heat in order to protect the components and/or assemblies from destruction due to overheating. Often, very large and material-intensive heat sinks are used for this purpose, the production of which is very expensive.

In conventional solutions, heat is dissipated by cooling using a cooling plate. When cooling with such a conventional cooling plate, the heat transfer from the electrical component, which may have a copper layer, to the cooling medium is achieved by applying a material, such as thermally conductive paste, to the thermal interface, thereby dissipating the generated heat. However, such heat interface material has proven to be disadvantageous. Firstly, it constitutes a further heat transfer with thermal resistance, and secondly, it is subject to wear, which gradually degrades its effectiveness during operation. The surface area of the cooling plate is also increased, or the number and performance of the components are reduced, in order to dissipate a larger amount of heat. Neither of the two options proves to be sufficient. Since the installation space in the housing of such a power supply is limited, the cooling surface cannot be expanded indefinitely. Reducing the performance of individual components is also not a viable solution. Overall, inadequate cooling of the electrical components results in costs.

One particularly challenging area is a process for plasma excitation, in particular plasma processing, such as coating, e.g., PVD, CVD, or etching. Such processes are used in the manufacturing of semiconductors such as microprocessor components and/or memory chips. Here, the requirements for reliability, durability, and process repeatability are particularly high. At the same time, the required performance levels are also very high. Furthermore, the required output modulations, e.g., in modern electrical power converters with an high-frequency amplifier assembly or pulsed high voltage supply with pulse shaping, have steadily increased recently. One requirement for high-frequency amplifier assemblies may be, for example, the ability to be pulsed at a plurality of different power levels, which is called multi-level pulsing (MLP). A further requirement for high-frequency amplifier assemblies can be, for example, the ability to be frequency-adjustable, and thus to be able to react quickly to load changes, which is called auto-frequency-tuning (AFT). Another requirement may be, for example, the ability to provide a very high direct voltage, e.g., greater than or equal to 2 kV, in particular greater than or equal to 7 kV, pulsed, with pulse frequencies greater than or equal to 1 kHz, in particular greater than or equal to 10 kHz, most preferably greater than or equal to 200 kHz. With all these requirements, the demands on power semiconductor components installed in the high-frequency amplifier assembly and used to generate HF power also increase. In particular, there is also a growing need for these components to convert power, which cannot be delivered to the load under certain conditions, into heat. These losses, which are converted into heat, can be ≥500 W, and in particular ≥1 kW, in some applications. This heat must be dissipated from the power semiconductor components, otherwise these will be destroyed by overheating.

### SUMMARY

In an embodiment, the present disclosure provides a power electronics component, comprising a first electrically insulating substrate with an upper surface and a lower surface, the first electrically insulating substrate having an upper surface metallization layer on the upper surface and a lower surface metallization layer on the lower surface, and a semiconductor assembly mounted on the first electrically insulating substrate and having at least one first connection thermally and electrically connected to at least one first region of the upper surface metallization layer of the first electrically insulating substrate. The upper surface metallization layer of the first electrically insulating substrate faces the semiconductor assembly. The power electronics component comprises a second electrically insulating substrate with an upper surface and a lower surface mounted on the semiconductor assembly and having an upper surface metallization layer on the upper surface of the second electrically insulating substrate and a lower metallization layer on the lower surface of the second electrically insulating substrate. The semiconductor assembly has at least one second connection thermally and electrically connected to at least one second region of the lower surface metallization layer of the second electrically insulating substrate. The lower surface metallization layer of the second electrically insulating substrate faces the semiconductor assembly. The power electronics component comprises a first heat sink thermally connected to the lower surface metallization layer of the first electrically insulating substrate, the lower surface metallization layer of the first electrically insulating substrate facing away from the semiconductor assembly, the first heat sink having at least one first cooling channel through which coolant is configured to flow. The power electronics component comprises a second heat sink thermally connected to the upper surface metallization layer of the second electrically insulating substrate, the upper surface metallization layer of the second electrically insulating substrate facing away from the semiconductor assembly, the second heat sink having at least one second cooling channel through which coolant is configured to flow.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an embodiment of a power electronics component;

FIG. 1a shows an electrical power converter in an industrial process assembly, preferably a plasma process assembly or a heating assembly;

FIG. 2 shows an electronics component as part of an embodiment of a power electronics component;

FIG. 3 shows an embodiment of a power electronics component;

FIG. 4 shows an embodiment of the electronics component as part of an embodiment of a power electronics component;

FIG. 5 shows connection surfaces of an IGBT;

FIG. 6 shows a routing for a control connection of a semiconductor component laterally out of the power electronics component;

FIG. 7 shows a routing for a control connection of a semiconductor component laterally out of the power electronics component;

FIG. 8 shows an embodiment of a power electronics component;

FIG. 8a shows an electrical power converter in an industrial process assembly, preferably a plasma process assembly or a heating assembly;

FIG. 9 shows an embodiment of a power electronics component in an oblique view;

FIG. 10 shows an embodiment of a power electronics component;

FIG. 10a shows an electrical power converter in an industrial process assembly, preferably a plasma process assembly or a heating assembly; and

FIG. 11 shows a routing for a control connection of a semiconductor component out of the power electronics component.

### DETAILED DESCRIPTION

In an embodiment, the present disclosure provides a power electronics component and a method for joining a power electronics component that enable improved dissipation of the heat generated during the operation of power electronics components. Furthermore, an embodiment of the present disclosure provides an electrical power converter for an industrial process assembly that enables improved dissipation of the heat generated during the operation of power components. In an embodiment, the industrial process assembly is preferably a plasma process assembly or a heating assembly, comprising a high-frequency amplifier assembly. This high-frequency amplifier assembly comprises a previously mentioned power electronics component and is designed to generate high-frequency output power, in particular for plasma excitation such as plasma coating processes, preferably for the production of semiconductor structures.

In an embodiment, the power electronics component comprises a first electrically insulating substrate, which has a metallization layer on both its upper and lower surfaces, and a semiconductor assembly which is mounted on the first substrate and has at least one first connection which is thermally and electrically connected to at least one region of the metallization layer of the first substrate, which metallization layer faces the semiconductor assembly. In addition, the power electronics component comprises a second electrically insulating substrate which is mounted on the semiconductor assembly and has a metallization layer on its upper and lower surfaces, wherein the semiconductor assembly has at least one second connection which is thermally and electrically connected to at least one region of the metallization layer of the second substrate, which metallization layer faces the semiconductor assembly, a first heat sink which is thermally and electrically connected to the metallization layer of the first substrate, which metallization layer faces away from the semiconductor assembly, the first heat sink having at least one first cooling channel through which coolant can flow, and a second heat sink which is thermally, and in particular also electrically, connected to the metallization layer of the second substrate, which metallization layer faces away from the semiconductor assembly, the second heat sink having at least one second cooling channel through which coolant can flow.

In an aspect, the power electronics component features a semiconductor assembly that can be cooled on both its upper and lower surface. For this purpose, the semiconductor assembly is thermally and electrically connected on its lower surface to the metallization of the first substrate, which metallization faces the semiconductor assembly, wherein the metallization of the first substrate, which metallization faces away from the semiconductor assembly, is thermally, and in particular also electrically, connected to the first heat sink. This arrangement allows for improved heat dissipation on the lower surface of the semiconductor assembly. The upper surface of the semiconductor assembly is thermally and electrically connected to the metallization of the second substrate, which metallization faces the semiconductor assembly, wherein the metallization of the second substrate, which metallization faces away from the semiconductor assembly, is thermally, and in particular also electrically, connected to a second heat sink. This also enables efficient heat dissipation on the upper surface of the semiconductor assembly. Heat dissipation is further improved by the fact that both the first and second heat sinks each have at least one cooling channel through which coolant can flow. Thanks to the power electronics component described here, even large amounts of heat generated on the side of the semiconductor assembly can be efficiently dissipated. It is particularly advantageous that the thermal coupling of the heat sinks takes place via the metallizations of the first and second substrates, because improved heat transfer is achieved by coupling the heat sinks via metallization layers. The solution described here provides a compact and mechanically stable component that cools the semiconductor assembly on both sides and provides improved heat dissipation.

In an aspect, a method for joining a power electronics component is disclosed. The method comprises the arranging of a semiconductor assembly on an first electrically insulating substrate which has a metallization layer on both its upper and lower surfaces, and the establishing of at least one thermal and electrical connection between at least one first connection of the semiconductor assembly and at least one region of the metallization layer of the first substrate, which metallization layer faces the semiconductor assembly, Furthermore, the method comprises the arranging of a second electrically insulating substrate, which has a metallization layer on both its upper and lower surfaces, on the semiconductor assembly, and the establishing of at least one thermal and electrical connection between at least one second connection of the semiconductor assembly and at least one region of the metallization layer of the second substrate, which metallization layer faces the semiconductor assembly. Furthermore, the method comprises the arranging of a first heat sink on the first substrate, wherein the first heat sink has at least one first cooling channel through which coolant can flow, the establishing of a thermal and electrical connection between the first heat sink and the metallization layer of the first substrate, which metallization layer faces away from the semiconductor assembly, the arranging of a second heat sink on the second substrate, wherein the second heat sink has at least one second cooling channel through which coolant can flow, and the establishing of a thermal and electrical connection between the second heat sink and the metallization layer of the second substrate, which metallization layer faces away from the semiconductor assembly.

In an aspect, the power electronics component comprises a semiconductor assembly and a first electrically insulating substrate on which the semiconductor assembly is mounted and which has a metallization layer on each of its upper and lower surfaces, wherein at least one connection of the semiconductor assembly is thermally and electrically connected to at least one region of the metallization layer of the first substrate, which metallization layer faces the semiconductor assembly. Furthermore, the power electronics component includes a first heat sink, the first side of which, facing the first substrate, is thermally and electrically connected to the metallization layer of the first substrate, which metallization layer faces away from the semiconductor assembly. Furthermore, the power electronics component comprises an additional electrically insulating substrate which has a metallization layer on both its upper and lower surfaces, wherein the additional substrate is mounted on the second side of the first heat sink, which second side is opposite the first side and wherein the second side of the first heat sink is thermally, and in particular also electrically, connected to the metallization layer of the additional substrate, which metallization layer faces the first heat sink.

In the power electronics component according to this solution, the lower surface of a semiconductor assembly is cooled. For this purpose, the semiconductor assembly is thermally and electrically connected to the metallization of a first substrate, which metallization faces the semiconductor assembly. A thermal and electrical connection to the first heat sink is formed via the metallization of the first substrate, which metallization faces away from the semiconductor assembly. The heat generated on the side of the semiconductor assembly can therefore be efficiently transferred via the metallization layers of the first substrate to the first heat sink and dissipated there. The side of the heat sink facing away from the semiconductor assembly is connected to an additional substrate. For this purpose, the first heat sink is thermally, and in particular also electrically, connected to the metallization of the additional substrate facing the heat sink. The first heat sink is therefore connected to the first substrate on its upper surface and to the additional substrate on its lower surface. This sandwich assembly creates a mechanically stable component. Another advantage is that additional assemblies and components can be placed on the additional substrate, the heat generated by which during operation can also be dissipated via the first heat sink. In particular, this would include, for example, control circuits that generate, for example, the control signals required for the operation of power components. However, the use of the additional substrate is not limited to control circuits; rather, the additional substrate can be used for any type of component and assembly.

In an aspect, a method for joining a power electronics component is disclosed. The method comprises the arranging of a semiconductor assembly on an first electrically insulating substrate which has a metallization layer on both its upper and lower surfaces, and the establishing of at least one thermal and electrical connection between at least one connection of the semiconductor assembly and at least one region of the metallization layer of the first substrate, which metallization layer faces the semiconductor assembly. Furthermore, the method includes the arranging of a first heat sink on the first substrate and the establishing of a thermal and electrical connection between a first side of the first heat sink facing the first substrate and the metallization layer of the first substrate, which metallization layer faces away from the semiconductor assembly. Furthermore, the method comprises the arranging of an additional electrically insulating substrate, which has a metallization layer on both its upper and lower surfaces, on the second side of the first heat sink, which second side is opposite the first side, and the establishing of a thermal and electrical connection between the second side of the first heat sink and the metallization layer of the further substrate, which metallization layer faces the first heat sink.

To describe the structure of the power electronics component, the present disclosure includes terms such as “on,” “upper surface,” “lower surface” to describe the geometric arrangement of the components of the power electronics component. This information refers to a power electronics component placed on a horizontal surface. The use of these terms is not to be understood as restrictive with regard to the spatial orientation of the power electronics component. Rather, the power electronics component can be used in any spatial orientation. In particular, the power electronics component can be used in any installation position.

In an aspect, the semiconductor assembly comprises one or a plurality of semiconductor components.

The semiconductor assembly is preferably arranged in a “bare die layer”. The term “bare die layer” here refers to a layer in which one or a plurality of semiconductor devices are arranged as “bare dies.” The term “bare dies” originates from English usage. The terms “bare chips,” “die” or “chip” are also frequently used synonymously. This refers to integrated electronic components that are not conventionally installed in a plastic or ceramic housing, but are further processed without a housing. They are applied directly to the conductor structure of the substrate and can be electrically connected to surrounding components or conductor structures by means of bonding, in particular by means of chip bonding. Bonding, as used here, refers to the connection of bare dies to other components or conductor structures.

The bare die layer can contain areas, in which no semiconductor devices are arranged. These areas can be filled with a filler material. This filler material can be designed to improve stability, reduce mechanical stresses and/or improve electrical insulation, for example by increasing air and/or creepage distances.

The term “connection” here refers to any type of connection that the semiconductor assembly can have, for example: collector connection, emitter connection, drain connection, source connection, control connection, test connection. In particular, it could be a power connection, for example: collector connection, emitter connection, drain connection, source connection. Each connection can have a connection surface with which it can be contacted to one of the metallizations. A power connection can have a relatively large area of 2 mm² or more, in particular.

An electrical connection refers in particular to a high-quality, low-resistance and low-inductance connection. It should preferably have a contact resistance of 0.2 Ω or less and preferably a contact inductance of 5 nH or less.

A “thermal connection” refers in particular to a high-quality thermal connection with low thermal resistance.

The requirement arises from predictable power dissipation, e.g., in a semiconductor module, such as a transistor, a diode, in particular a PIN diode, e.g., for switching HF power between different paths, or of a combination of transistor with diode, and system thermal resistance from bare die to the coolant. The system thermal resistance is calculated as the sum of all thermal resistances. The first important thermal resistance, which cannot be influenced by the cooling assembly, is the thermal resistance between the bare die or chip and the bare die cooling surface. The manufacturer specifies it as RthJ/C (short for junction/case). It depends on the cooling surface of the semiconductor module and, for currently common transistors, is between 0.7 K/W and 0.8 K/W.

As mentioned previously, modern plasma process applications, in particular in the manufacturing of semiconductors such as computers or memory chips, place high demands on electrical power converters. These can often only be achieved if the semiconductor module(s) are designed to absorb a significant amount of power loss. This could be, for example, greater than or equal to 1 kW. To achieve this, a thermal resistance of less than or equal to 0.15 K/W measured from bare die or chip to coolant should preferably be achieved. After extensive simulations and tests, it was determined that this can be achieved with the present power electronics component. Further improvements are not ruled out and are always welcome.

In an aspect, the first heat sink is realized at least partially in the form of a layered structure made of thermally bonded metal foils, preferably copper foils. Such a method of manufacturing a monolithic heat sink is disclosed, for example, in DE4315580A1, in which individual metal foils are structured at least partially by means of laser processing and/or stamping and/or manufactured by means of electroplating processes and then joined together. Such a process will hereinafter be called a ‘metal layer bonding process.’ Preferably, the first heat sink is manufactured at least partially using a metal layer bonding process. In an aspect, the metal foils are joined together using a bonding process under high pressure and at high temperature.

In an aspect, the first heat sink is made of copper. Copper has very good thermal conductivity and electrical conductivity. For example, oxide layers can be formed on the surfaces of copper layers, which are then welded together, wherein the temperature is preferably selected to be so high that the oxide layers melt, but the metal foils do not. This is how the metal foils combine to form a monolithic heat sink. If the metal foils are made of copper, for example, this is also referred to as direct copper bonding, abbreviated DCB.

In an aspect, the metal foils have a thickness of 0.4 mm or less, in particular 0.25 mm or less. This allows for very effective heat dissipation.

In an aspect, the first heat sink has at least one first cooling channel through which coolant can flow, wherein the at least one first cooling channel is realized in the form of at least one recess provided in the metal foils. For example, the structuring or production of the metal foils can be carried out in such a way that, after the layers are joined together, closed channels are created through which a cooling medium can flow.

It is advantageous if the first heat sink is connected to the metallization layer of the first substrate, which metallization layer faces away from the semiconductor assembly, by at least one of the following: sintering, pressing, a metal layer joining method, in particular DCB, at least one soldered joint.

In an aspect, the first heat sink is manufactured at least partially by means of an additive manufacturing process, preferably by means of selective laser melting. Such an additive manufacturing process is disclosed, for example, in EP1672690B1—Micro heat sink. The now more common term ‘additive manufacturing process’ is described there by means of the selective laser melting process. However, the term ‘additive manufacturing process’ can also include processes other than selective laser melting. An additive manufacturing process is characterized by the fact that the structure is gradually applied from the same material. The material can be melted during application. Lasers are currently a suitable option for achieving particularly fine structures.

In an aspect, a multitude of cooling pins are arranged in the first cooling channel or in a sub-area of the first cooling channel, said cooling pins extending into the first cooling channel. The cooling pins are surrounded by the coolant flowing in the cooling channel. This allows for improved thermal coupling.

It is advantageous if the first heat sink comprises a coolant inlet and a coolant outlet, both of which are fluidically connected to the first cooling channel, wherein the first heat sink is designed such that the first heat sink can be detachably mounted on a cooling unit comprising a first fluid port and a second fluid port, and that, when the first heat sink is mounted on the cooling unit, a first fluidic connection can be formed between the coolant inlet of the first heat sink and the first fluid port of the cooling unit, and a second fluidic connection can be formed between the coolant outlet of the first heat sink and the second fluid port of the cooling unit. The cooling unit is designed to supply coolant to the first heat sink and to drain the coolant away again. The first heat sink can, for example, be designed in such a way that fluid-tight fluidic connections can be produced between the first heat sink and the cooling unit when the first heat sink is secured to the cooling unit. For example, the power electronics component can be removed from the cooling unit if required. This allows, for example, a detachable attachment of the power electronics component within the cooling unit. This is particularly advantageous in terms of maintenance and repair.

In an aspect, the first heat sink is a micro heat sink and the semiconductor assembly is an electronic component. A micro heat sink is designed to cool a single electronic component. This allows for individual cooling that can be adapted to the heat generated by the electronic component.

In an aspect, the first substrate is materially bonded to the first heat sink on a first cooling wall, wherein the power electronics component is designed so that, during operation, the coolant is guided through the first cooling channel at a predetermined operating pressure, wherein the distance between the first cooling channel and the first cooling wall is selected to be so small that the first heat sink, without the first substrate being materially bonded thereto, cannot ensure sufficient structural stability and/or tightness at the specified operating pressure, and the first substrate and its materially bonded connection with the first heat sink on the first cooling wall is designed in such a way that the power electronics component can ensure this sufficient structural stability and tightness. A typical predetermined operating pressure can be, for example, 3 bar or more overpressure relative to ambient pressure. There are a plurality of options for designing the substrate and its materially bonded connection with the heat sink on the cooling wall so that the cooling assembly can ensure this sufficient structural stability and tightness. The substrate can, for example, have a certain minimum thickness throughout. For example, the substrate can be made thicker in places where the distance between the cooling channel and the substrate is particularly thin, in order to ensure stability in these areas alone. However, the structural stability of the substrate is just one parameter. The strength of the materially bonded connection between the substrate and the heat sink is also important. The more stable the substrate can be designed, the thinner it can be.

It is advantageous if the first cooling channel is characterized in that its cross-section has at least partially a geometric shape, whose width, measured parallel to the first cooling wall, decreases in the direction of the first cooling wall, and wherein the geometric shape of the cross-section at the first cooling wall has a distance to the substrate which is designed such that, at the predetermined operating pressure of the coolant, the first heat sink, without the first substrate being materially bonded thereto, cannot ensure sufficient structural stability and/or tightness.

It is advantageous if at least one control connection and at least one first power connection are arranged on the first side of the semiconductor assembly and at least one second power connection is arranged on the second side of the semiconductor assembly. In this embodiment, the first power connection can be electrically contacted from the first side and the second power connection from the second side. This enables large-area electrical contacting of the power connections. Given the high currents flowing through the power connections, this is advantageous. In the following, a number of solutions are discussed for routing the control connection, which typically carries less current compared to the power connections, out of the power electronics component.

In an aspect, the metallization layer facing the first side of the semiconductor assembly has at least one first metallization region for electrically contacting at least one control connection of the semiconductor assembly and at least one second metallization region for electrically contacting at least one first power connection of the semiconductor assembly, wherein the at least one first metallization region and the at least one second metallization region are electrically separated from each other, and wherein at least one first metallization region extends towards the side of the component and can be electrically contacted from the side of the component. In this embodiment, at least one control connection can be electrically contacted through at least one first metallization region and at least one first power connection through at least one second metallization region. This allows the control connection to be routed to the side of the component.

It is advantageous if the at least one first metallization region and the at least one second metallization region of the metallization layer are separated from each other by means of an etching process. The etching process allows the metallization layer to be divided into different, electrically separated metallization regions.

In an aspect, a contacting structure is provided for electrically contacting the control connection, which contacting structure is arranged on the metallization facing the first side of the semiconductor assembly, wherein the contacting structure comprises at least one insulating material layer and a conductive layer, and wherein the conductive layer is electrically connected to the control connection and is routed to the side of the component. It is particularly advantageous if the conductive layer used to route the control connection is electrically separated from other metallization regions by means of layers of insulating material.

In an aspect, at least one control connection of the semiconductor assembly is electrically contacted via at least one through-connection extending through the first heat sink, also known as a via. At least one of the control connections can be contacted from the side facing away from the semiconductor assembly via the at least one via.

In the area of one or both heat sinks, via insulation can be provided for a via, which protects the through-connection from electrical contact with the heat sink.

In an aspect, the second heat sink is manufactured at least partially by means of a metal layer bonding method, in particular a DCB method. This is advantageous if the metallization layers of the second substrate and the metal foils of the second heat sink are connected in a process. This means that all the metal foils that form the heat sink and the metallization layer of the substrate are joined together in one process.

In an aspect, the first heat sink is manufactured at least partially by means of a metal layer bonding method, in particular a DCB method. This is advantageous if the metallization layers of the first substrate and the metal foils of the first heat sink are connected in a process. This means that all the metal foils that form the heat sink and the metallization layer of the substrate are joined together in one process.

In an aspect, the second heat sink is realized at least partially in the form of a layered structure made of thermally bonded metal foils, preferably copper foils. For example, metal foils can be structured at least partially by means of laser processing and/or stamping and/or manufactured by means of electroplating processes and then joined together. Preferably, the second heat sink is manufactured at least partially using a metal layer bonding process. Preferably, the metal foils are joined together using a bonding process under high pressure and at high temperature.

In an aspect, the second heat sink is made of copper. Copper has very good thermal conductivity and electrical conductivity. For example, oxide layers can be formed on the surfaces of copper layers, which are then welded together, wherein the temperature is preferably selected to be so high that the oxide layers melt, but the metal foils do not. This is how the metal foils combine to form a monolithic heat sink. If the metal foils are made of copper, for example, this is also referred to as direct copper bonding, abbreviated DCB.

In an aspect, the metal foils have a thickness of 0.4 mm or less, in particular 0.25 mm or less. This allows for very effective heat dissipation.

In an aspect, the second heat sink is connected to the metallization layer of the second substrate, which metallization layer faces away from the semiconductor assembly, by at least one of the following: sintering, pressing, a metal layer joining method, in particular DCB, at least one soldered joint.

In an aspect, the first substrate and/or the second substrate is one of the following: ceramic substrate, direct bonded copper (DBC), insulated metal substrate (IMB), active metal brazed (AMB), thick film substrate.

In an aspect, the first substrate is arranged substantially parallel to the second substrate. The semiconductor assembly is surrounded at the bottom by the first substrate and at the top by the second substrate, each of which is thermally connected to the associated heat sinks. This allows for efficient heat dissipation to both sides. The symmetrical arrangement of the substrates results in a space-saving design and a favorable geometry with regard to the installation of the component.

In an aspect, the first heat sink and the second heat sink are both micro heat sinks, and the semiconductor assembly is an electronic component. In this embodiment, the first and second heat sinks are each designed as micro heat sinks. A micro heat sink is designed to cool a single electronic component. In the present case, the electronic component is cooled by both the first and the second heat sink, both of which are designed as micro heat sinks. The electronic component, together with the two micro heat sinks, can, for example, be removed from a larger assembly and reinserted into it, which is advantageous from the point of view of maintenance and repair. This allows for individual cooling that can be adapted to the heat generated by the electronic component.

It is advantageous if the component comprises a control electronics, which is arranged on the side of the additional substrate facing away from the first heat sink, wherein at least one connection of the control electronics is thermally and electrically connected to at least one region of the metallization layer, which metallization layer faces the control electronics. Preferably, a control electronics that generates the signals required for controlling the semiconductor assembly can be placed on the additional substrate. In this way, the control signals can be generated for the semiconductor assembly located on the first substrate in the immediate spatial environment of the semiconductor assembly. This allows signal interference in the control signals, which can be caused, for example, by the coupling of electromagnetic interference signals, to be reduced or avoided. The at least one via allows, for example, the control signals generated by the control electronics to be routed directly to the semiconductor assembly in order to control, for example, power electronics components there. In the area of the heat sink, via insulation can be provided to protect the through-connection from electrical contact with the heat sink.

In an aspect, at least one connection of the control electronics is electrically connected to a connection of the semiconductor assembly via at least one via which passes through the first heat sink.

In an aspect, the first heat sink has at least one first cooling channel through which coolant can flow. It is advantageous if the first heat sink is realized in the form of a layered structure made of thermally bonded metal foils, preferably copper foils, and the first cooling channel is realized in the form of at least one recess provided in the metal foils.

In an aspect, the first substrate and/or the additional substrate is one of the following: ceramic substrate, direct bonded copper (DBC), insulated metal substrate (IMB), active metal brazed (AMB), thick film substrate.

In an aspect, the first substrate is arranged substantially parallel to the additional substrate. By arranging the first substrate on the lower surface of the first heat sink and the additional second, parallel substrate on the upper surface of the heat sink, a compact geometric structure is created in which the heat sink is stabilized by the two substrates. The coolant inlet and coolant outlet of the heat sink can, for example, be accessible from the side of the heat sink or, alternatively, be routed through the additional substrate.

The advantages of the present disclosure are also provided by an electrical power converter for an industrial process assembly, preferably a plasma process assembly or a heating assembly, comprising a power electronics component as described above or below. The electrical power converter can, in particular, be designed to generate high-frequency output power. High-frequency output power here refers to an output power in the range of 1 kW or more, in particular 10 kW or more, preferably 100 kW or more at frequencies ≥20 kHz, preferably ≥200 kHz, and in particular ≥2 MHz.

As mentioned at the above, such a power converter is particularly dependent on very efficient and reliable cooling, which can be achieved particularly well with such a power electronics component.

EP3317966B1 describes an assembly with a printed circuit board for cooling on a metallic cooling plate. For this purpose, the printed circuit board has a bottom layer, wherein the bottom layer is designed as a metallic layer that serves as a reference mass. However, the heat transfer from the printed circuit board to the cooling plate is not optimal. The circuit board often does not lie flat on the cooling plate. In order to counteract the lack of heat transfer due to this disadvantage, thermally conductive paste is used, but this is disadvantageous in the manufacturing process and can age, which can further deteriorate the heat transfer.

In an aspect, the power electronics component comprises two power semiconductor components, in particular transistors, each having a first and a second power connection and a control connection, wherein both power semiconductor components, in particular transistors, are connected with one of their power connections in series, wherein a direct current or direct voltage is connected to the remaining power connections. This can be done directly, for example, or via a filter or an inductor. Furthermore, a control electronics can be provided which is connected to the control connections of the power semiconductor components and the control electronics is designed to control the power semiconductor components, in particular, the transistors such that they can generate a high-frequency power by switching from a first conductive state into a second conductive state, wherein the conductivity of the two states is different. Such an assembly can be operated very efficiently, e.g., in Class D, Class E or Class F or Class F⁻¹ operation. Such an operation generates less power loss than, for example, Class A or Class B operation. In combination with the very good cooling provided by the described power electronics component, an even further improved supply to industrial processes can be achieved, for example by allowing them to be operated at higher power. Typical operating classes for generating HF power are described, for example, in EP 1 601 098 B1.

In an aspect, the two power semiconductor components, in particular transistors, can each be connected with their first power connection to a common connection point, in particular ground connection point, wherein the power semiconductor components, in particular transistors, are of the same design in particular and are arranged on the multilayer, printed circuit board. This allows for further improvements in cooling and increased power output.

In an aspect, one of the two power semiconductor components, in particular transistors, is connected with its first power connection to the other power semiconductor component, in particular transistor and with its second power connection at a common connection point, wherein the power semiconductor components, in particular transistors, are of the same design in particular and are arranged on the multilayer, printed circuit board. This allows for further improvements in cooling and increased power output.

In an aspect, a power transformer with a primary winding and a secondary winding can be arranged on the printed circuit board, wherein the primary winding is connected to the at least one power connection of the power semiconductor components, in particular transistors. The primary winding and the secondary winding of the power transformer can each be designed as planar conductor tracks arranged in different positions on the printed circuit board. The printed circuit board can have a thermal connection with the cooling unit. This allows for further improvements in cooling and a further increase in power output.

In an aspect, the thermal connection with the cooling unit can have a thermally conductive leveling layer which is firmly connected with its first surface to the first surface of the printed circuit board. In addition, the thermal connection can alternatively or additionally have a connecting layer which is firmly connected with its first surface to the second surface of the thermally conductive leveling layer and with its second surface to the cooling unit.

The cooling unit can exhibit a heat-distributing characteristic here. It can be electrically conductive or insulating.

“Firmly connected” means that the connection is firm and durable, such as bonding, welding, soldering or pressing, and preferably only separable with high heat and/or mechanical pressure.

In particular, the connection can be established as a material bond. This prevents air entrapment and ensures good thermal conduction properties.

The thermally conductive leveling layer is suitable for conducting heat from the printed circuit board towards the cooling unit. It can compensate for unevenness caused, for example, by conductor tracks, windings or contact pads on the lower surface of the printed circuit board and provide a homogeneous and flat plane in the direction of the cooling unit.

The thermally conductive leveling layer can consist of or comprise a prepreg or unreinforced adhesive. The insulating printed circuit board and the heat distributor can be connected by heating and pressing together a prepreg inserted therebetween. “Prepreg” is a common material designation, which is an abbreviation of “pre-impregnated.” This usually refers to pre-impregnated, mostly planar, flat textile semi-finished products with a thermoplastic or thermosetting matrix, such as unidirectional layers of threads, fabrics or scrims with threads often arranged at right angles.

Prepregs are cured under temperature and pressure to produce components. For example, they are prefabricated in web form, wound on rolls. The term “prepreg” includes not only unidirectionally reinforced or flat semi-finished products, but also other preforms of basically any shape, which in the broadest sense consist of or comprise a fiber-filled, uncured thermosetting matrix. The matrix is in a partially cross-linked state and is pasty to solid, but can be liquefied again by heating.

Prepregs are machine-processable and are therefore often used in automated processes. They produce consistent and high quality. Advantages are the low undulation and high fiber volume content thereof. Curing at high temperatures enables short cycle times in further processing. Processing requires high investment costs, e.g., for autoclaves, laying robots and refrigerated storage. Such prepregs are generally used to join a plurality of printed circuit boards together to form a multilayer printed circuit board. In order to ensure a secure and long-lasting joint, the materials to be joined should have very similar properties regarding their expansion when heated. However, this is not necessarily the case with the printed circuit board and the heat distributor, in particular if the heat distributor is made of ceramic. This is an argument initially against such a connection. However, ceramics have very good thermal conductivity and at the same time very good electrical insulating properties and also low dielectric losses when insulating high-frequency signals of high voltage. Contrary to expectations, tests have shown that even with small dimensions, a secure and long-lasting joining of materials with different properties can be provided, such as ceramic with FR-4 and/or ceramic with PTFE material. “Small dimensions” means a composite area of less than 400 cm² and/or with a maximum length of 20 cm.

The connecting layer can comprise an adhesive on the basis of a resin. It can be thinner than the thermally conductive leveling layer.

The connecting layer can comprise an adhesive film.

Together, the two layers can form a solid connection with good thermal conduction properties to the cooling unit.

In an aspect, such an electrical power converter will improve the properties of a power supply system that has LDMOS transistors as the elements to be cooled, as disclosed, for example, in DE 10 2013 226 537 A1, EP 3 317 964 B1, EP3 317 965 B1. The load capacity of LDMOS transistors in such power supply systems often reaches its limits because they get too hot, even though neither their maximum voltage rating nor their maximum current rating is reached. This means that with an improvement in cooling as described above and below, such power supply systems can be operated much more reliably.

In an aspect, such an electrical power converter will improve the properties of a power supply system that provides very high voltages at its output, in particular voltages greater than or equal to 1 kV, particularly preferably greater than or equal to 2 kV, and in particular greater than or equal to 4 kV. Particularly preferred is when they are also provided in a pulsed manner, as described for example in EP 4 235 737 A1 as a ‘high-power generator.’ Since the switching elements described there must switch on even when a voltage is applied to their power connections, these switching operations are particularly high in losses. EP 4 235 737 A1 describes a very complex cooling process, which can be improved with the device and/or method described here.

In an aspect, such an electrical power converter will improve the characteristics of a power supply system that has a coupling unit, in particular a phase-shifting coupling unit, preferably a 90° hybrid coupler, as is described, for example, in DE 10 2013 226 537 A1 or WO 2020/025547 A1. This coupling unit described therein can be used independently of other features as described in DE 10 2013 226 537 A1 or WO 2020/025547 A1. The coupling unit can preferably have a first and a second planar inductor, as also described in DE 10 2013 226 537 A1.

In an aspect, such an electrical power converter will improve the characteristics of a power supply system that uses GaN transistors as the element to be cooled. Such power converters are described, for example, in WO 2010/091696 A1 or WO 2010/091697 A1.

In an aspect, such an electrical power converter will improve the characteristics of a power supply system that uses SiC transistors as the element to be cooled. Such power converters are described, for example, in WO 2020/025547 A1.

The patent publications DE 10 2013 226 537 A1, EP 3 317 964 B1, EP3 317 965 B1, WO 2010/091696 A1, WO 2010/091697 A1, WO 2020/025547 A1 and EP 4 235 737 A1 are incorporated in their entirety by reference herein.

Further advantageous configurations are described in more detail below with reference to a plurality of exemplary embodiments shown in the drawings, to which the development described here is not limited, however.

In the following description of preferred embodiments, identical reference numerals designate identical or comparable components.

The semiconductor assembly 28 described in the following figures comprises electronic components and assemblies for power applications, in particular power semiconductor components such as transistors or diodes, especially PIN diodes e.g., for switching HF power between different paths, or a combination of transistor with diode, which are designed for example for currents ≥10A and voltages ≥400V. These can generate a high amount of waste heat during operation, which must be dissipated during operation. The load capacity of such electronic components and assemblies often reaches its limits because they get too hot, even though neither their maximum voltage rating nor their maximum current rating is reached.

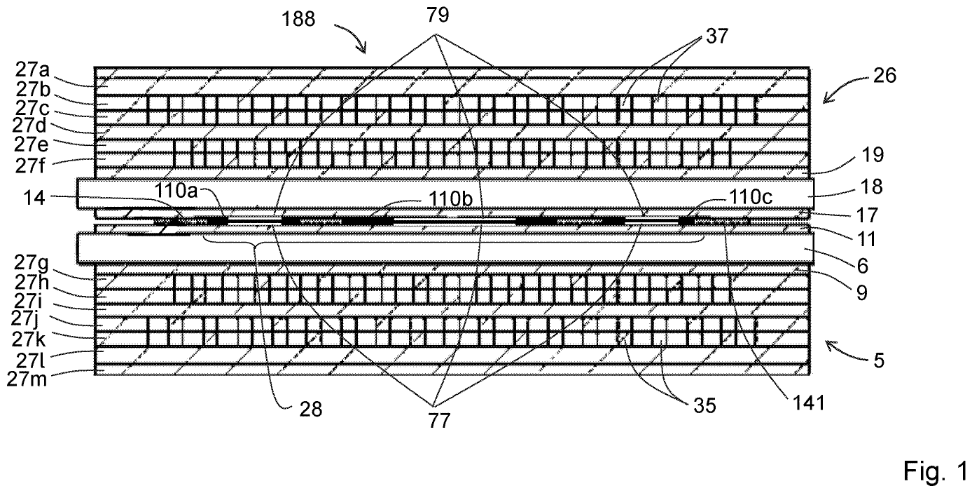

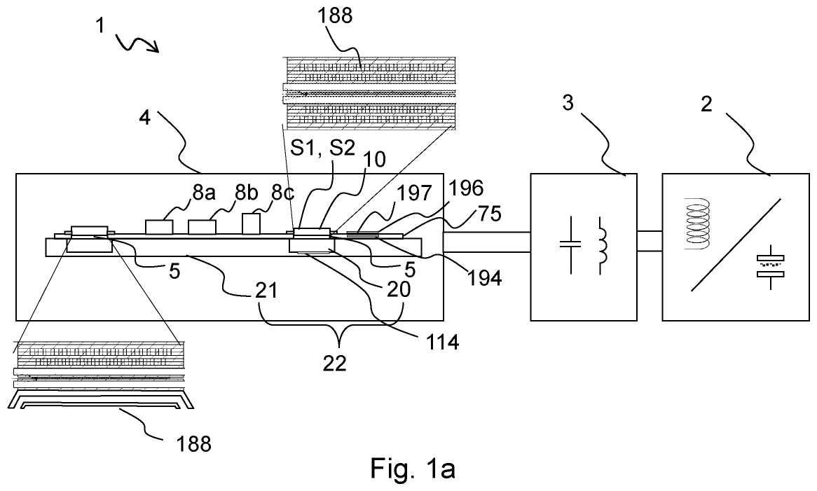

FIG. 1 shows a first power electronics component 188, in which double-sided cooling is provided for the heat dissipation of the components, i.e., cooling from both the upper and lower surface of the components. FIG. 1 shows a semiconductor assembly 28 in a bare die layer 14, which can include one or a plurality of semiconductor devices 110a-c. These semiconductor components 110a-c can represent power semiconductor components, e.g., transistors and/or diodes for switching and conducting very high power, very high current and/or very high voltage. The power output can be, for example, 10 kW or more. The voltage can be, for example, 400 V or more, in particular 1 kV or more. The current can be, for example, 10 A or more, in particular 50 A or more. The switching frequency can be, for example, 10 kHz or more, preferably 100 kHz or more, in particular 1 MHz or more.

The semiconductor devices are firmly connected on their lower surface to the conductor structures 11a-c of a metallization 11, which is applied to the upper surface of a first substrate 6. This metallization 11 on the upper surface of a first substrate 6 can also be called upper surface metallization 11. The bare die semiconductor elements and the upper surface metallization 11 can be joined together, for example, by means of at least one soldered connection, in particular a silver solder connection, at least one welded connection, by means of sintering or a comparable process. Such a materially bonded connection exhibits very good and stable heat transfer.

A heat sink made of metal can dissipate heat very effectively. However, it can have the disadvantage of being electrically conductive in certain circumstances. Because of its electrical conductivity, there is a risk that currents will be induced in it. These could lead to additional unwanted losses. However, the dimensions of the heat sink can be reduced due to its particularly high heat dissipation efficiency to such an extent that the induction of currents could also be significantly reduced.

The bare die layer 14 can have areas where no semiconductor devices are arranged. These areas can be filled with a filler material 141. This filling material 141 can be designed to improve stability, reduce mechanical stresses and/or improve electrical insulation, for example by increasing air and/or creepage distances.

The semiconductor devices of the semiconductor assembly 28 mounted on the first substrate 6 have at least one first connection 77 which is thermally and electrically connected to at least one first region of the upper surface metallization 11 of the first substrate 6, which metallization faces the semiconductor assembly 28.

A second electrically insulating substrate 18 is mounted here to the semiconductor assembly 28 and has a metallization layer 17, 19 on both its upper and lower surfaces.

The semiconductor components of the semiconductor assembly 28 have at least one second connection 79, which is thermally and electrically connected to at least one second region of the metallization layer 17 of the second substrate 18, which metallization layer faces the semiconductor assembly 28.

The first substrate 6 can preferably be a ceramic substrate. Examples of suitable ceramic materials include aluminum oxide ceramic, beryllium oxide ceramic, aluminum nitride ceramic, and sapphire. The metallization 11 can be applied to the first substrate 6 using a previously mentioned bonding process, for example by means of direct bonded copper. With this method, a copper foil can be bonded to the substrate, for example the ceramic substrate, under pressure and high temperature. Alternatively, metallization processes such as IMB (insulated metal substrate) or AMB (active metal brazed) could be considered. Such a materially bonded connection exhibits very good and stable heat transfer.

A metallization 9 is also applied to the side of the first substrate 6 facing away from the bare die layer 14. This can be called the lower surface metallization layer 9. The lower surface metallization 9 can also be applied to the first substrate 6 by means of a bonding process, for example by means of direct bonded copper. The first heat sink 5 is firmly connected to the lower surface metallization 9. Such a materially bonded connection exhibits very good and stable heat transfer.

In the example shown in FIG. 1, the first heat sink 5 is manufactured using a metal layer bonding process. In this process, individual metal foils 27a-m, preferably copper foils, are structured at least partially by means of laser processing and/or punching and/or manufactured by means of electroplating processes and then joined together. The structuring or production process is carried out in such a way that, after the layers are joined together, first closed cooling channels 35 are created through which a cooling medium can flow. By means of a cooling channel structure, the coolant can be directed specifically to the areas of the first heat sink 5 that require particularly high heat dissipation. Preferably, the metal foils are joined together using a bonding process under high pressure and at high temperature. For this purpose, oxide layers can be formed on the surfaces of the copper layers, which are then welded together, wherein the temperature is preferably selected to be so high that the oxide layers melt, but the metal foils do not. This is how the metal foils combine to form a monolithic heat sink. If the metal foils are made of copper, for example, this is also referred to as direct copper bonding, abbreviated DCB. The metal foils 27a-m preferably have a thickness of 0.4 mm or less, in particular 0.25 mm or less.

There are different ways to produce the structure shown in FIG. 1. According to an embodiment, the production of the first substrate 6, provided with metallizations 9 and 11, and the first heat sink 5 each takes place in separate steps. The first heat sink 5 is then firmly connected to the metallization 9, for example by means of a bonding process, in particular by means of direct copper bonding. In this way, the lower surface metallization 9 can be part of the heat sink 5, in particular the monolithic heat sink. Other, less preferred, joining methods of the heat sink 5 with the metallization can include, for example: soldering, welding or sintering. According to a second, alternative manufacturing process, all layers, i.e., both the first substrate 6 and the metal foils 27g-m, from which the first heat sink 5 is formed, are bonded together in a bonding process under high pressure and at high temperature, preferably by means of direct copper bonding and direct bonded copper.

In an aspect, the metallization 11 is also applied to the upper surface of the substrate 6 in the same step.

The shaping of the metallization 11 into the conductor structures 11a, 11b, 11c can then be carried out, for example, by an etching process.

In the first power electronics component 188 shown in FIG. 1, the upper surface of the bare die layer 14 is also cooled by means of a second heat sink 26. In this way, effective heat dissipation of the bare die layer 14 is enabled from both sides. For this purpose, a second substrate 18 is arranged on the upper surface of the bare die layer 14, which is provided with metallizations 17, 19 on both sides. The bare die layer 14 is firmly connected to conductor structures of the metallization 17 of the second substrate 18 and the second substrate 18 is firmly connected to the second heat sink 26 via the metallization 19. Just like the first heat sink 5, the second heat sink 26 can also be manufactured from a plurality of metal foils 27a-f using a metal layer bonding process. The second heat sink 26 has at least one second cooling channel 37 for dissipating heat from the first power electronics component 188.

Since the layer structure on the upper surface of the bare die layer 14 corresponds to the layer structure on the lower surface of the bare die layer 14, reference is made to the description of the structure mounted on the lower surface of the bare die layer 14 with regard to the various possibilities for connecting the layers.

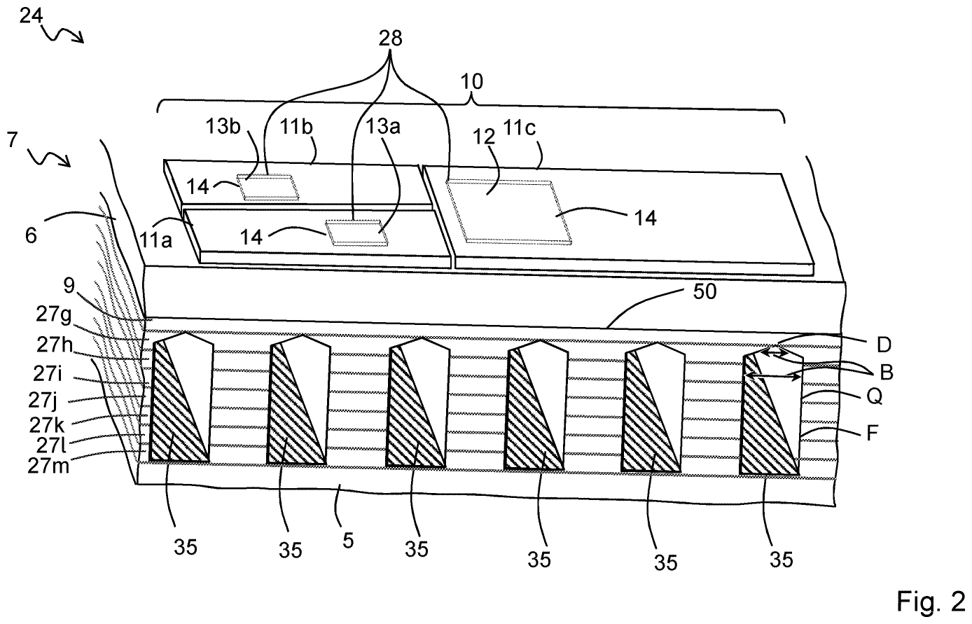

Particularly efficient dissipation of the heat generated by the semiconductor components can be achieved in the first power electronics component 188 shown in FIG. 1 if the cooling channels 35 and 37 are arranged in the immediate vicinity and at a short distance from the respective substrates 6 and 18. For the first heat sink 5, such an embodiment is shown in FIG. 2. For example, “small distance” means a distance of less than 50μm.

FIG. 1a shows an industrial process assembly 1, preferably a plasma process assembly or a heating assembly.

The industrial process assembly 1 has:
an electrical power converter 4,
a load 2, preferably a plasma process or heating process, e.g., an induction or microwave heating process, wherein the load 2 is electrically connected to the electrical power converter 4, such that the electrical power converter 4 can supply the load 2 with the required electrical power,
optionally an additional adaptation unit 3 which is connected between the power converter 4 and the load 2.

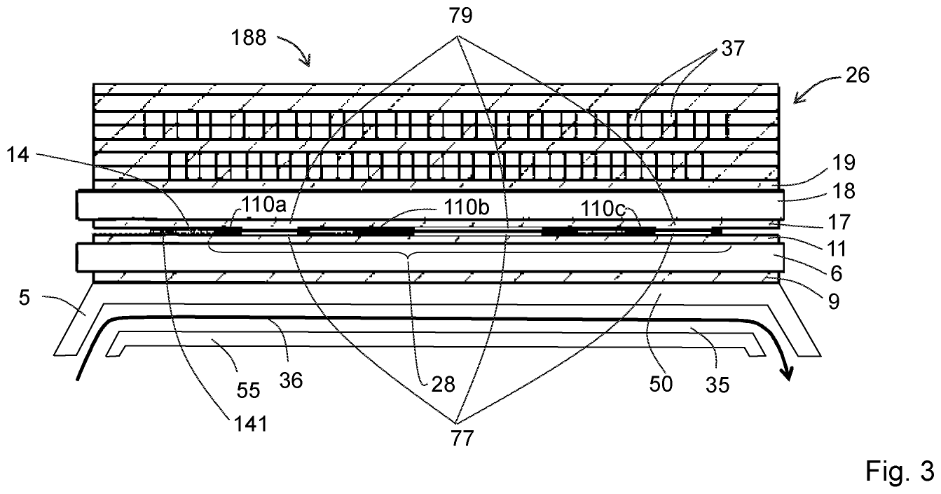

The power converter 4 has:
two of the first power electronics components 188, as previously described, for example, in the description of FIG. 1 and subsequently, for example, in the description of FIG. 3,
a cooling unit 22, which, as described above and below, has one or a plurality of distribution units 20 and a carrier unit 21,
a printed circuit board 75,
a unit 10 to be cooled, in particular an electric unit, preferably a semiconductor assembly, preferably having a power semiconductor component,
further electronic components 8a, 8b, 8c,
wherein the further electronic components 8a, 8b, 8c and the unit 10 to be cooled are arranged on or against a printed circuit board 75 and are connected to electrical contacts,
wherein the unit 10 to be cooled has a fixed, in particular materially bonded, connection to the heat sink 5, 85.

Two power semiconductor components, in particular transistors S1 and S2, are arranged on or against the printed circuit board 75 as the unit 10 to be cooled, wherein each of these devices has a first and a second power connection and a control connection, and both transistors S1 and S2 can be connected in series via their power connections. A direct current or direct voltage can be connected to the remaining power connections. A control electronics 114 can be connected to the control connections of the power semiconductor components.

On the printed circuit board 75, a power transformer 197 is also arranged, having a primary winding 196 and a secondary winding 194. The primary winding 196 and the secondary winding 194 of the power transformer 197 are each designed as planar conductor tracks, which are arranged in different positions on the printed circuit board 75. The printed circuit board has a thermal connection with the cooling unit 22.

The thermal connection with the cooling unit 22 can have a thermally conductive leveling layer, which is firmly connected with its first surface to the first surface of the printed circuit board 75, and a connecting layer, which is firmly connected with its first surface to the second surface of the thermally conductive leveling layer and with its second surface to the heat distributor.

FIG. 2 shows an electronics assembly 24 with a cooling assembly 7 and with an electrical unit 10 to be cooled, which is preferably a semiconductor assembly 28. The electronic assembly 24 can be part of a power electronics component 188, as described above and below. The cooling assembly 7 contains the first heat sink 5 and the first substrate 6 which is materially bonded to it. The first heat sink 5 has a first cooling channel 35, through which coolant can flow in a specified direction. The first heat sink 5 further comprises a cooling wall 50 on the side of the first cooling channel 35 facing the electrical unit 10 to be cooled. The first substrate 6 is materially bonded to the first heat sink 5 on the cooling wall 50. On the side facing away from the first substrate 6 and the first heat sink 5, the electrical unit 10 is mechanically fixed to the first substrate 6. The electrical unit 10 contains:
a conductor structure 11a, 11b 11c, collectively referred to as metallization 11,
a semiconductor assembly 28 comprising:
a semiconductor module 12, which can be 3-pin, in particular a transistor, or a PIN diode e.g., for switching HF power between different paths,
further 2-pole semiconductor modules to be cooled 13a, 13b, e.g., diodes.

The 3-pin semiconductor module 12 can be designed as a bare die layer 14. This allows for very direct heat coupling. It can be materially bonded and firmly connected, e.g., by a soldered connection to the conductor structure 11c. This results in a particularly low and stable thermal resistance.

One or a plurality of, in particular all, 2-pole semiconductor modules 13a, 13b to be cooled can be designed as a bare die layer 14. This allows for very direct heat coupling. It can be materially bonded and firmly connected, e.g., by a soldered connection to the conductor structure 11c. This results in a particularly low and stable thermal resistance.

The 3-pin semiconductor module 12 and the 2-pin semiconductor modules 13a, 13b are also collectively referred to as semiconductor devices.

A metallization 9 is also applied to the side of the first substrate 6 facing away from the bare die layer 14.

The cooling assembly 7 is designed so that, during operation, the coolant is routed through the first cooling channel 35 at a predetermined operating pressure which is above the ambient pressure which is applied to the first substrate 6 on the side of the electrical unit 10 to be cooled. A distance D between the first cooling channel 35 and cooling wall 50 is selected to be so small that the first heat sink 5, without the first substrate 6 being materially bonded thereto, cannot ensure sufficient structural stability and/or tightness at the specified operating pressure. The first substrate 6 and its materially bonded connection with the first heat sink 5 on the cooling wall 50 is designed in such a way that the cooling assembly 7 can ensure this sufficient structural stability and tightness. The first heat sink 5 is designed to be monolithic.

In particular, the distance D can be equal to or less than the thickness of the metallization 9 and/or less than or equal to 50 μm.

The first cooling channel 35 is characterized in that its cross-section Q has at least partially a geometric shape F, whose width B, measured parallel to the cooling wall 50, decreases in the direction of the cooling wall 50. The geometric shape F of the cross-section Q on the cooling wall 50 has at least partially a distance D to the first substrate 6, which is designed to be so small that, at the predetermined operating pressure of the coolant, the first heat sink 5, without the first substrate 6 being materially bonded thereto, cannot ensure sufficient structural stability and/or tightness. A typical predetermined operating pressure can be, for example, 3 bar or more overpressure relative to ambient pressure.

As an alternative or at least partially supplementary to the production of the heat sinks 5, 26 by means of a metal layer bonding process illustrated in FIG. 1, at least one of the heat sinks 5, 26 can be produced by means of an additive process, for example by means of selective laser melting. Additive manufacturing processes are characterized by the fact that the structure is gradually applied from the same material. The material can be melted during application. To produce such a heat sink, for example, the metallization applied to the side of the respective substrate facing away from the bare die layer 14 can be further built up using an additive manufacturing process.

Additive manufacturing processes enable the layer-by-layer construction of components directly from digital models by selectively applying material. In contrast to subtractive methods, where material is removed, additive processes offer high flexibility in the design of complex geometries and are particularly efficient in material consumption. Furthermore, additive manufacturing processes provide for manufacturing monolithic components with cavities that have complex internal structures. These technologies are widely used in prototype development, small-batch production and increasingly also in industrial production.

A heat sink made of metal using an additive manufacturing process has a surface structure unique to this manufacturing process. The structure is characterized by a rough surface, because in the additive manufacturing process the metal is first melted and then hardened by cooling. This roughness is therefore similar to a very fine crystal structure, such as those found in nature. This roughness can lead to a particularly large surface area between the coolant and the metal. This increase in surface area can enhance heat transfer between the heat sink and the coolant. Furthermore, turbulence can form particularly well on the rough surface, which can also have a beneficial effect on the heat transfer between the heat sink and the coolant. The heat sink therefore exhibits this rough surface structure, characteristic of the additive manufacturing process, at least partially, preferably predominantly, on the wall facing the coolant.

One or a plurality of outer surfaces of the heat sink can be ground or shaped after the additive manufacturing process step. This allows for advantageous heat transfer from a winding or electrical conductor of the heat-generating component and/or from a core of the heat-generating component to the heat sink.

In an aspect, the heat sink is manufactured using selective laser melting (SLM). Selective laser melting is an additive manufacturing process used to produce metal components. The metal powder is applied layer-by-layer and precisely melted and solidified using a high-performance laser to create a three-dimensional component. A heat sink manufactured from metal using SLM has a surface structure unique to this manufacturing process. The structure is characterized by a particularly rough surface.

SLM is frequently used in industries that place high demands on component quality and precision, such as aerospace, medical technology, automotive engineering and tool manufacturing. Thanks to its ability to manufacture components with complex internal structures and high material utilization, the process is increasingly used for demanding, customized applications.

Advantages of SLM processes include the production of complex geometries. The process enables the production of highly complex and delicate structures that are difficult or impossible to create using conventional manufacturing methods. Furthermore, the SLM process allows for a wide variety of materials. SLM can be performed with various metals such as aluminum, titanium, stainless steel and nickel, as well as numerous alloys with these materials, making it attractive to numerous industries. The SLM process is also very economical for small production runs. Especially in the production of prototypes and small series, SLM can be more economical than conventional manufacturing processes, as no special tools or molds are required. In the past, the SLM process using copper was still in its infancy and was considered particularly expensive.

The disadvantages of the SLM manufacturing process are the duration and the cost. For the same component size, a heat sink manufactured using an additive manufacturing process, in particular an SLM manufacturing process, would be many times more expensive than a heat sink manufactured by machining, pressing, or casting. In the past, this manufacturing process was therefore discouraged for larger production runs and cost-critical developments. However, since the size of the heat sink can be significantly reduced due to its considerably increased efficiency, costs and manufacturing time can also be reduced. This makes heat sinks manufactured using additive manufacturing, in particular the SLM manufacturing process, an attractive option again. Furthermore, since this also significantly reduces the weight and dimensions of the heat-generating component, such a heat sink becomes even more interesting. As development progressed, even more heat can be dissipated from a smaller area on the heat-generating component. This made it possible to improve the conductor and/or the core of the heat-generating component, in particular to further reduce its size, which in turn allowed the dimensions of a power converter to be further reduced. Components surrounding the heat-generating component could also be arranged in a more space-saving manner. This also reduced the length of supply lines to these components. This led to a reduction in electromagnetic interference and susceptibility to malfunctions in the device, and to a further reduction in power loss. All these positive effects combined justify the higher manufacturing costs of a heat sink produced using additive manufacturing, in particular the SLM manufacturing process.

In an aspect, the heat sink comprises a single-piece main body. This means that the heat sink is designed as a single, integrated component. This can enable increased mechanical stability and improved heat dissipation. By avoiding a multi-part construction, potential weak points that could arise from connections or joints can be avoided. This can contribute to the longevity and reliability of the heat-generating component. This is particularly advantageous in connection with the liquid cooling of the heat sink, since the one-piece main body does not require seals or the like, which would be necessary in multi-piece designs. This can reduce the risk of coolant leakage, which can further increase the operational safety and efficiency of the cooling system. This design can also simplify the manufacturing and assembly of the heat-generating component if fewer individual parts are required and the heat sink can be manufactured more efficiently as an integral part of the heat-generating component.

FIG. 3 shows an embodiment of the first power electronics component 188, in which the heat dissipation of the semiconductor components on the upper surface is carried out by means of the second heat sink 26, which is manufactured by means of a metal layer bonding process. The first heat sink 5, intended for cooling the lower surface of the semiconductor components, is manufactured in the embodiment of FIG. 3 using an additive manufacturing process. It can be seen that the first heat sink 5 has a first cooling channel 35, through which a cooling current 36 flows. This cooling flow 36 cools the first cooling wall 50, which is firmly connected to the metallization 9 mounted on the lower surface of the first substrate 6. It is particularly advantageous if the metallization 9 of the first substrate 6, which was applied to the first substrate 6 for example by means of direct bonded copper, is built up to the first heat sink 5 by means of the additive manufacturing process. Alternatively, the first heat sink 5 could also be manufactured separately using the additive manufacturing process and then firmly connected with the metallization 9, for example by soldering, welding or sintering.

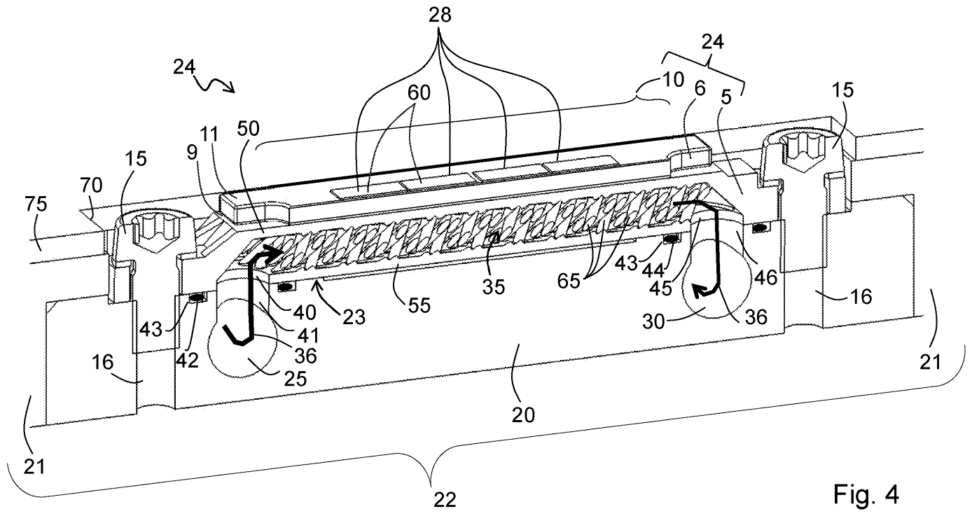

The embodiment shown in FIG. 3 can be designed such that a planar extended bare die layer 14, comprising a multitude of semiconductor devices, is cooled on both sides. Alternatively, the heat sink arrangement shown in FIG. 3 can also be designed in the form of a microcooler for cooling individual semiconductor components or groups of semiconductor components. One such solution is shown in FIG. 4.

FIG. 4 shows a further embodiment of the electronics component 24 as part of a fourth embodiment of a power electronics component 100, 188, 118. The electronics component 24 is shown in the longitudinal section. The electronics component 24 comprises a first cooling element 5 that is designed to cool an electrical unit 10 that is attached to the first heat sink 5. The electrical unit 10 to be cooled can in particular be an electric unit, preferably a semiconductor assembly.

The first heat sink 5 is releasably connected to a cooling unit 22. In the example shown in the figures, the cooling unit 22 comprises a distribution unit 20 designed here for example to supply the first heat sink 5 with coolant. Furthermore, the cooling unit 22 comprises here for example a carrier unit 21 into which the distribution unit 20 is inserted. The cooling unit 22 has a receptacle 23 into which the first heat sink 5 can be releasably inserted. The first heat sink 5 is then secured to the cooling unit 22 by way of at least one securing means 15, preferably by way of one or a plurality of screws. The cooling unit 22 has at least one receiving device 16 for the at least one securing means 15. To separate the first heat sink 5 from the cooling unit 22, at least one securing means 15 is first undone. The first heat sink 5, together with the electrical unit 10 to be cooled attached thereto, can then be removed from the receptacle 23 of the cooling unit 22.

In an aspect, the electrical unit 10 is mechanically and thermally connected to the first heat sink 5. The electrical unit 10 can be connected to the first heat sink 5, for example, by way of one or a plurality of soldered connections. In an embodiment, the electrical unit 10 can be connected to the first heat sink 5, for example by way of sintering. Alternatively, the electrical unit 10 can be welded to the first heat sink 5. As another, albeit less advantageous, alternative, the electrical unit 10 could also be connected to the first heat sink 5 by way of a layer of thermally conductive paste. However, an aspect of the development described here is to ensure that the connection between the electrical unit 10 to be cooled and the first heat sink 5 is made using as little additional material as possible and is as thin as possible. In the course of the considerations, simulations and experiments for this development described here, it became apparent that this is in particular made possible when the heat sink with fluid flowing through it is fixedly connected, in particular by a material bond, to the electrical unit 10 to be cooled. This can be achieved, for example, by soldering, sintering, pressing or direct copper bonding (DCB). The term ‘fixedly’ here can mean: ‘only destructively detachable,’ This means using means of connection that cannot be detached even with tools without destroying either the electrical unit 10 to be cooled or the first heat sink 5 or both components. It was further recognized that such a solution will only be feasible if a new solution can be found for the interchangeability of the circuit board component with electronic components and, in particular, with the electrical unit 10 to be cooled secured thereto. This is achieved with the disclosed first heat sink 5.

The first heat sink 5 and the electrical unit 10 to be cooled that is mechanically fixedly connected to the first heat sink 5 together form an electronics assembly 24. This electronics assembly 24 can be inserted into the receptacle 23 of the cooling unit 22 and removed from this receptacle 23.

The cooling unit 22 is designed to supply coolant to the first heat sink 5 mounted on the cooling unit 22 and to discharge the coolant again after the coolant has flowed through the first heat sink 5. A first flow channel 25 through which coolant can be supplied to the first heat sink 5 can be seen within the cooling unit 22. A second flow channel 30 through which the coolant can be discharged can be seen within the cooling unit 22. The first heat sink 5 has a first cooling channel 35, through which the coolant can flow. A coolant inlet 40 is provided at a first end of the first cooling channel 35 and a coolant outlet 45 is provided at the second end of the first cooling channel 35 opposite the first end. The coolant inlet 40 and the coolant outlet 45 are fluidically connected to the first cooling channel 35.

The cooling unit 22 comprises a first fluid port 41 that is fluidically connected to the first flow channel 25, and a second fluid port 46 that is fluidically connected to the second flow channel 30. When the first heat sink 5 is inserted and subsequently secured in the receptacle 23, a first fluidic connection is produced between the first fluid port 41 and the coolant inlet 40, as well as a second fluidic connection between the second fluid port 46 and the coolant outlet 45.

To seal the first fluidic connection, a first sealing ring 42 is arranged in a groove 43 between the cooling unit 22 and the first heat sink 5, wherein the sealing ring 42 entirely surrounds the first fluid port 41. A second sealing ring 44 that entirely surrounds the second fluid port 46 is likewise provided at the second fluid port 46 and is arranged in a groove 43 between the cooling unit 22 and the first heat sink 5. When the at least one securing means 15 is secured, for example when the at least one screw is tightened, the first heat sink 5 is pressed against the first fluid port 41 and the first sealing ring 42 as well as against the second fluid port 46 and the second sealing ring 44. This application of pressure produces a liquid-tight first fluidic connection and a liquid-tight second fluidic connection between the cooling unit 22 and the first heat sink 5.

As shown in FIG. 4, a cooling flow 36 can be formed within the cooling unit 22. The coolant flows from the first flow channel 25 via the first fluid port 41 and the coolant inlet 40 into the first cooling channel 35. The coolant flows through the first cooling channel 35 and is discharged again via the coolant outlet 45, the second fluid port 46 and the second flow channel 30.

The first heat sink 5 has a first cooling wall 50 on the side facing the electrical unit 10 to be cooled. On the side of the first heat sink 5 facing away from the electrical unit 10 to be cooled, the first cooling channel 35 is bounded by a second cooling wall 55 that is opposite the first cooling wall 50. Preferably, the second cooling wall 55 is configured parallel to the first cooling wall 50.

In the example shown in FIG. 4, the electrical unit 10 comprises a semiconductor assembly 28, which includes, for example, an arrangement of transistors 60, which can in particular be designed as bare die semiconductor devices. The heat generated during operation of the transistors 60 is dissipated via the coolant flowing in the first cooling channel 35. To achieve cooling of the transistors 60 on both sides, a second heat sink can be applied to the upper surface of the transistors 60. This second heat sink could, for example, be a heat sink manufactured using a metal layer bonding process or a heat sink manufactured using an additive manufacturing process. Such an arrangement is also provided for one or a plurality of PIN diodes, e.g., for switching HF power between different paths, or a combination of transistor and diode.

To improve thermal exchange between the coolant flowing through the first cooling channel 35 and the first heat sink 5, a multitude of cooling pins 65 that extend into the first cooling channel 35 from the first cooling wall 50 and/or from the second cooling wall 55 can be arranged inside the first cooling channel 35. The cooling pins 65 have coolant flowing around them and ensure improved thermal coupling between the first heat sink 5 and the coolant.

It can also be seen in FIG. 4 that the electrical unit 10, together with the first heat sink 5 arranged therebelow, can be arranged within a first recess 70 of a printed circuit board 75.

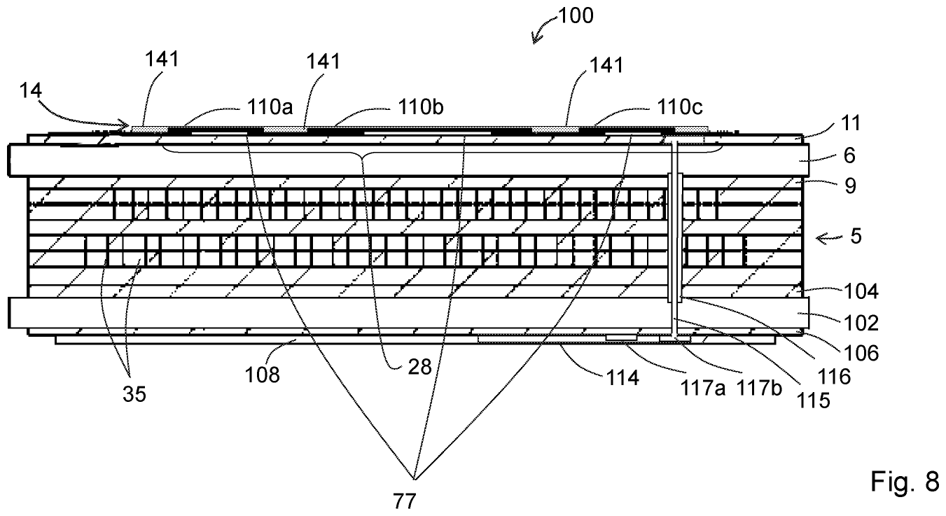

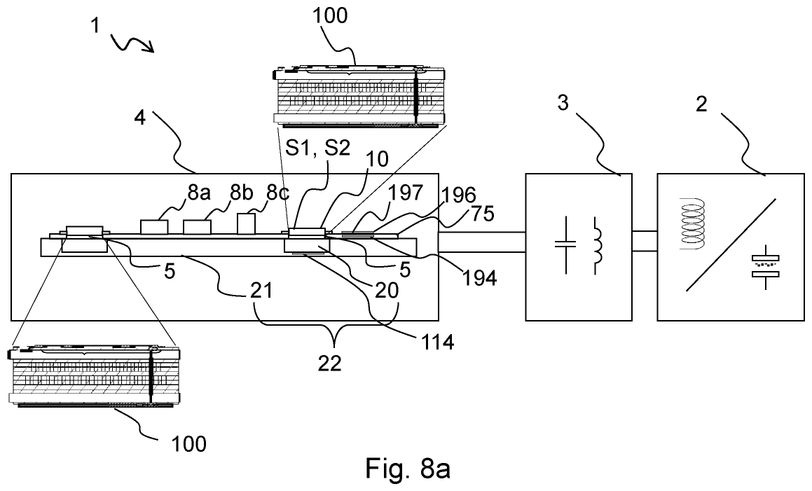

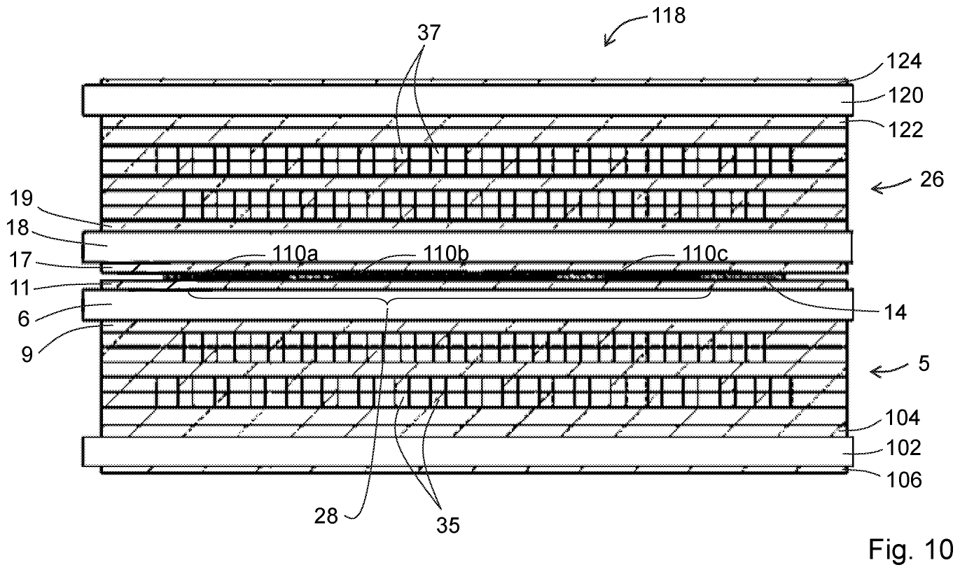

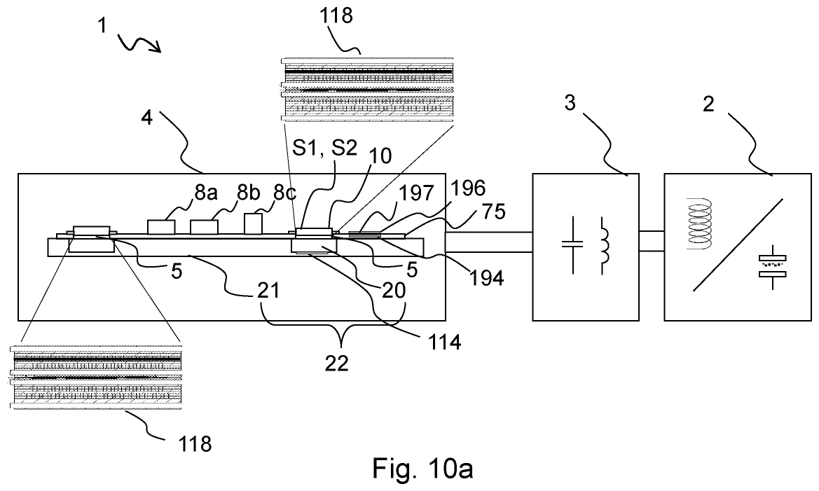

The arrangements shown in FIGS. 1 to 4 can have an additional electrically insulating substrate 102, which has a metallization layer 104, 106 on both its upper and lower surfaces, wherein the additional substrate 102 can be mounted on the second side of the first heat sink 5, which second side is opposite the first side and/or on the second side of the second cooling element 26, which second side is opposite the first side. For example, the second side of the first heat sink 5 can be thermally connected to the metallization layer 104 of the additional substrate 102, which metallization layer faces the first heat sink 5. Alternatively or additionally, for example the second side of the second heat sink 26 can be thermally connected to the metallization layer of the additional substrate, which metallization layer faces the second heat sink 26. This can be seen from a comparison of FIGS. 1 to 4 with FIGS. 8 and 10.

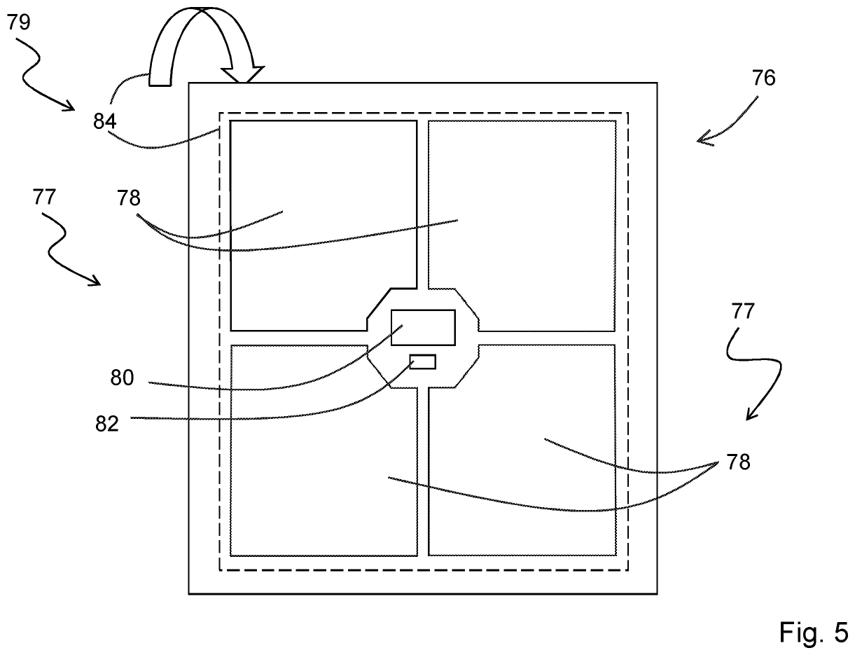

FIG. 5 shows how a bare die component, for example designed as an IGBT 76, can be electrically contacted. The IGBT 76 has on its first side first connections 77, in particular designed as four emitter connection surfaces 78, a control connection surface 80 and a test connection surface 82 required for testing purposes. On the rear side, the IGBT 76 has a second connection 79, in particular designed as a collector connection surface 84. These connection surfaces can be electrically contacted by the conductor structures 11a-c of the metallizations 11 and/or 17. In particular, the collector connection surface 84 is also electrically connected directly to the connection of the bare die component with the conductor structure 11c. In particular, the emitter connection surfaces 78 are connected to a conductor structure of the opposite metallization 17. This too can take the form of conductor structures, as will be explained in more detail below and with further illustrations.

The assembly can also be reversed, i.e., the collector connection surface 84 can be directly electrically connected to the connection of the bare die component of a conductor structure of the metallization 17, and the emitter connection surfaces 78 can be connected to a conductor structure 11c of the opposite metallization 11.

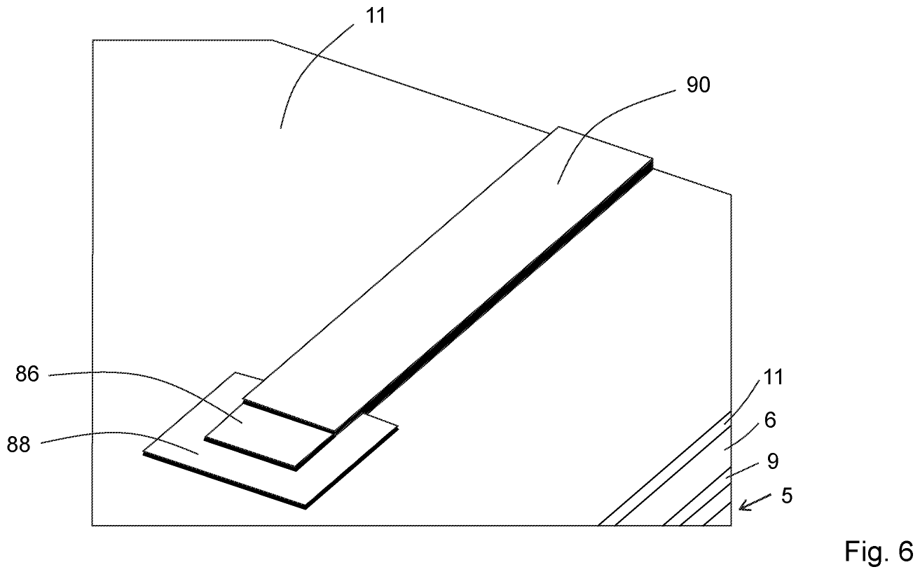

When cooling semiconductor components from both sides, the question arises as to how a control connection of a semiconductor component can be routed to the outside. There are different possibilities for this, which are described below in FIGS. 6 to 8.

FIG. 6 shows the metallization 11 applied to the first substrate 6. The metallization 11 can, for example, be made of copper, preferably copper coated with NiAu. The coating can serve as a diffusion barrier. First, an insulating material layer 86 is applied to the metallization 11, extending laterally outwards from the location of the respective control connection. A conductor track layer 88 made of conductive material is then applied to this insulating material layer 86, which layer being designed to electrically contact the control connection of the respective semiconductor component. The insulating material layer 86 can have a recess at the location of the gate connection. A conductor track insulating material layer 90 is then applied to this conductor track layer 88 made of conductive material, which insulating material layer also extends laterally outwards from the location of the control connection. The conductor track layer 88 made of conductive material is thus insulated from the metallization 11 by the insulating material layer 86 and from the bare die layer 14 by the conductor track insulating material layer 90. The control connection can be electrically contacted via the conductor track layer 88 made of conductive material, which is routed to the outside.

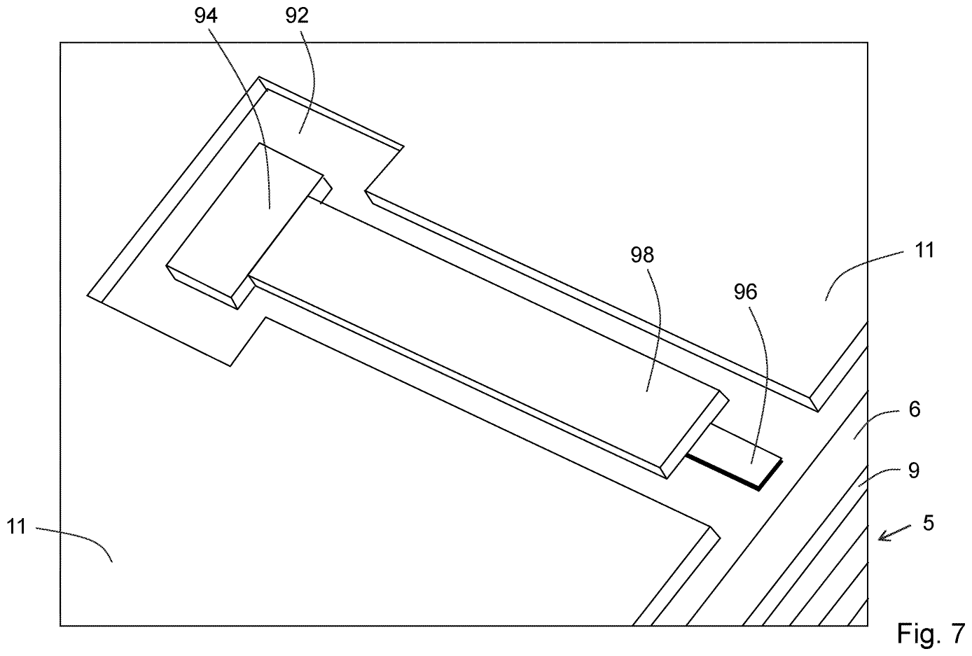

FIG. 7 shows a further option for routing the control connection of the semiconductor component laterally to the outside, so that the control connection can be electrically contacted from the side of the power electronics component.

FIG. 7 shows the metallization 11 applied to the first substrate 6. In the first step, the metallization 11 within the trench-shaped area 92 is removed, e.g., etched away, up to the first substrate 6, leaving an inner area 94 of the metallization 11. This inner area 94 extends laterally to the outside from the control connection of the semiconductor device and is isolated from the rest of the metallization 11 by the trench-shaped area 92 running around the inner area 94. Subsequently, within a sub-area 96 of the inner area 94, etching is carried out to a certain depth, leaving part of the metal as a control connection conductor track. Subsequently, a conductor track insulating material layer 98 is deposited onto this partially etched sub-area 96. This conductor track insulating material layer 98 insulates the control connection of the semiconductor component, which is routed laterally to the outside, from the bare die layer 14.

According to another aspect of the development described here, at least one of the heat sinks has an additional substrate arranged on the side of the heat sink facing away from the bare die layer 14, so that the heat sink is arranged in a sandwich structure between two substrates.

FIG. 8 shows a second power electronics component 100 according to the second aspect of the development described here. FIG. 8 shows that the first substrate 6 is arranged below the bare die layer 14, with the metallization 11 of the first substrate 6 being connected to the bare die layer 14 as described above. The first heat sink 5 is mounted on the side of the first substrate 6 facing away from the bare die layer 14, and an additional substrate 102 is arranged on the side of the first heat sink 5 facing away from the bare die layer 14. The additional substrate 102 has metallizations 104, 106 on both sides. The metallization 104 facing the first heat sink 5 is firmly connected to the first heat sink 5. The further metallization 106 is arranged on the side of the substrate 6 facing away from the heat sink 5 and can be designed like a previously described conductor structure for receiving electronic components, in particular semiconductor components. This further substrate 102 can increase the stability of the heat sink 5. In addition, the further metallizations 106 on the side of the substrate 6 facing away from the heat sink 5 provide for arranging drivers and/or measuring electronics with very short electrical paths to the power components of the bare die layer 14.

The first heat sink 5 is therefore arranged in a sandwich structure between the first substrate 6 and the additional substrate 102. The substrates 6 and 102 preferably consist of or comprise ceramic, and therefore, as a result of this sandwich structure, an additional mechanical stabilization of the first heat sink 5 is achieved. A further advantage is that one or a plurality of semiconductor devices, for example in a further bare die layer 108, can be arranged on the metallization 106 located on the side of the additional substrate 102 facing away from the first heat sink 5. The additional substrate 102 can therefore be used, for example, to accommodate driver and control circuits, e.g., a control electronics 114 for the actual power electronics unit. Electrical connections can be formed between the semiconductor components, e.g., the control electronics 114, which can be part of the further bare die layer 108, and the semiconductor components 110a-c of the bare die layer 14 arranged on the first substrate 6, using one or a plurality of vias 115 extending through the first heat sink 5. At least one connection 117a of the control electronics 114 can be thermally and electrically connected to at least one area of the further metallization layer 106, which metallization layer faces the first control electronics 114. At least one further connection 117b of the control electronics 114 can be electrically connected to a connection 119 of the semiconductor assembly 28 via at least one via 115, which runs, in particular insulated therefrom, through the first heat sink 5.

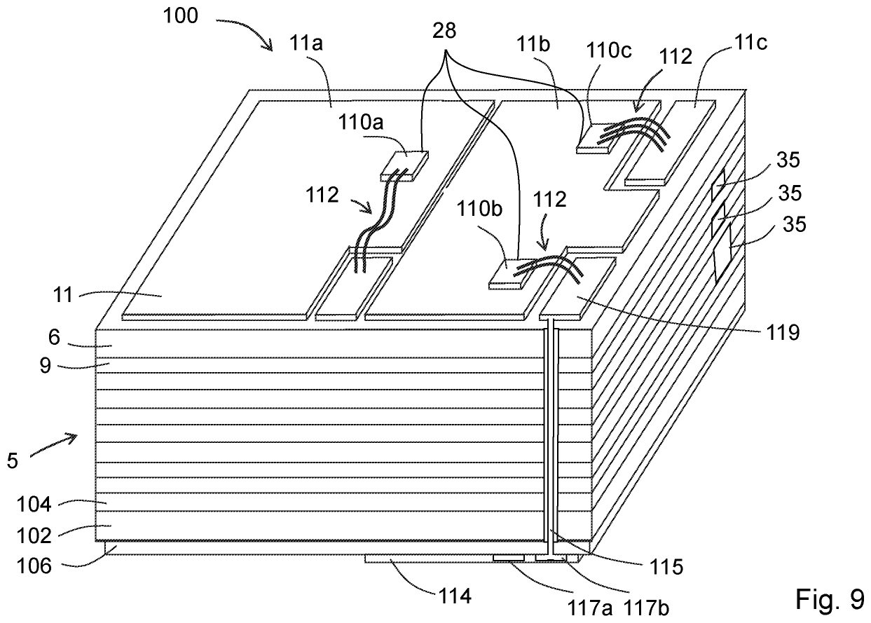

The second power electronics component 100 shown in FIG. 8 is shown again in an oblique view in FIG. 9. FIG. 9 shows the first substrate 6 with the metallizations 9 and 11 on both sides, the additional substrate 102 with the two metallizations 104 and 106 and the first heat sink 5 arranged between them. Semiconductor devices 110a, 110b, 110c are mounted on the upper surface of the metallization 11, which devices are part of the bare die layer 14. On the upper surface of the second power electronics component 100, wave-shaped connecting lines 112, in particular designed as bonding wires, can also be seen, which are intended to establish electrical connections between the semiconductor components 110a, 110b, 110c and the conductor structures on the metallization 11 by means of wire bonding.

On the side of the additional substrate 102 facing away from the first heat sink 5, further semiconductor components such as a control electronics 114 are arranged on the metallization 106, which can be connected, for example, via a through-connection, also called a “via” 115, to the semiconductor components 110a, 110b, 110c on the upper surface of the second power electronics component 100.

In the area of the heat sink 5, via insulation 116 can be provided, which protects the through-connection from electrical contact with the heat sink 5.

The first cooling channels 35 extend within the first heat sink 5.

The power electronics component 100 shown in FIG. 8 can optionally have a second heat sink 26, as shown, for example, in FIG. 1 or FIG. 10. This second heat sink 26 can be thermally connected to the metallization layer 19 of the second substrate 18, which metallization layer faces away from the semiconductor assembly 28. The second heat sink 26 can have at least one second cooling channel 37 through which coolant can flow.

FIG. 8a shows an industrial process assembly 1, preferably a plasma process assembly or a heating assembly.

The industrial process assembly 1 has:
an electrical power converter 4,
a load 2, preferably a plasma process or heating process, e.g., an induction or microwave heating process, wherein the load 2 is electrically connected to the electrical power converter 4, such that the electrical power converter 4 can supply the load 2 with the required electrical power,
optionally an additional adaptation unit 3 which is connected between the power converter 4 and the load 2.

The power converter 4 has:
two of the second power electronics components 100, as previously described, for example, in the description of FIG. 8 and subsequently, for example, in the description of FIG. 9,
a cooling unit 22, which, as described above and below, has one or a plurality of distribution units 20 and a carrier unit 21,
a printed circuit board 75,
a unit 10 to be cooled, in particular an electric unit, preferably a semiconductor assembly, preferably having a power semiconductor component,
further electronic components 8a, 8b, 8c,
wherein the further electronic components 8a, 8b, 8c and the unit 10 to be cooled are arranged on or against a printed circuit board 75 and are connected to electrical contacts,
wherein the unit 10 to be cooled has a fixed, in particular materially bonded, connection to the heat sink 5, 85.

Two power semiconductor components, in particular transistors S1 and S2, are arranged on or against the printed circuit board 75 as the unit 10 to be cooled, wherein each of these devices has a first and a second power connection and a control connection, and both transistors S1 and S2 can be connected in series via their power connections. A direct current or direct voltage can be connected to the remaining power connections. A control electronics 114 can be connected to the control connections of the power semiconductor components.

On the printed circuit board 75, a power transformer 197 is also arranged, having a primary winding 196 and a secondary winding 194. The primary winding 196 and the secondary winding 194 of the power transformer 197 are each designed as planar conductor tracks, which are arranged in different positions on the printed circuit board 75. The printed circuit board has a thermal connection with the cooling unit 22.

The thermal connection with the cooling unit 22 can have a thermally conductive leveling layer, which is firmly connected with its first surface to the first surface of the printed circuit board 75, and a connecting layer, which is firmly connected with its first surface to the second surface of the thermally conductive leveling layer and with its second surface to the heat distributor.

FIG. 10 shows a third power electronics component 118 which has a cooling structure of the type shown in FIG. 8 on both the upper surface and lower surface of the bare die layer 14. The first substrate 6 with the two metallizations 9 and 11, the heat sink and the additional substrate 102 with the two metallizations 104 and 106 are arranged on the lower surface of the bare die layer 14. The second substrate 18 with the metallizations 17 and 19, the second heat sink 26 and the additional substrate 120 with the metallizations 122 and 124 are arranged on the upper surface of the bare die layer 14. The first heat sink 5 has first cooling channels 35 and the second heat sink 26 has second cooling channels 37, through which coolant can flow.

FIG. 10a shows an industrial process assembly 1, preferably a plasma process assembly or a heating assembly.

The industrial process assembly 1 has:
an electrical power converter 4,
a load 2, preferably a plasma process or heating process, e.g., an induction or microwave heating process, wherein the load 2 is electrically connected to the electrical power converter 4, such that the electrical power converter 4 can supply the load 2 with the required electrical power,
optionally an additional adaptation unit 3 which is connected between the power converter 4 and the load 2.

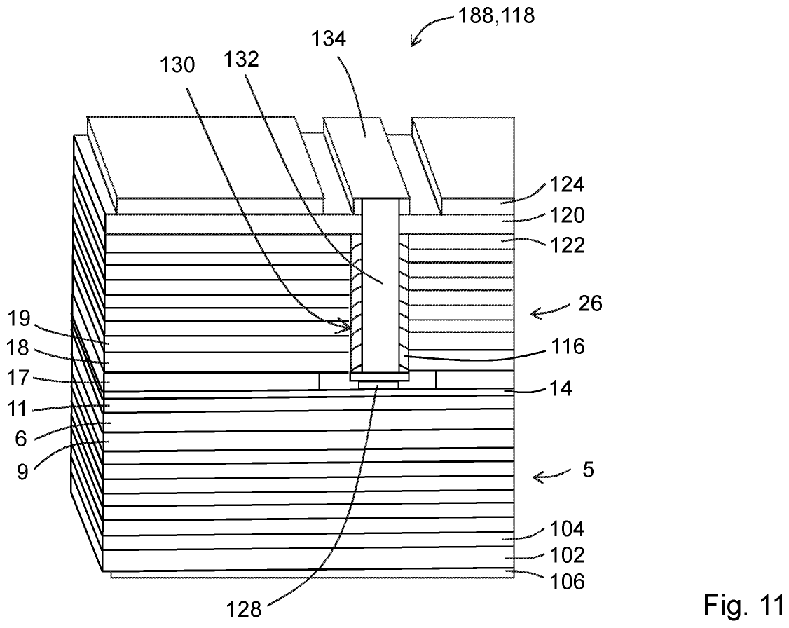

The power converter 4 has:
two of the first power electronics components 118, as previously described, for example, in the description of FIG. 10 and subsequently, for example, in the description of FIG. 11,
a cooling unit 22, which, as described above and below, has one or a plurality of distribution units 20 and a carrier unit 21,
a printed circuit board 75,
a unit 10 to be cooled, in particular an electric unit, preferably a semiconductor assembly, preferably having a power semiconductor component,
further electronic components 8a, 8b, 8c,
wherein the further electronic components 8a, 8b, 8c and the unit 10 to be cooled are arranged on or against a printed circuit board 75 and are connected to electrical contacts,
wherein the unit 10 to be cooled has a fixed, in particular materially bonded, connection to the heat sink 5, 85.

Two power semiconductor components, in particular transistors S1 and S2, are arranged on or against the printed circuit board 75 as the unit 10 to be cooled, wherein each of these devices has a first and a second power connection and a control connection, and both transistors S1 and S2 can be connected in series via their power connections. A direct current or direct voltage can be connected to the remaining power connections. A control electronics 114 can be connected to the control connections of the power semiconductor components.

On the printed circuit board 75, a power transformer 197 is also arranged, having a primary winding 196 and a secondary winding 194. The primary winding 196 and the secondary winding 194 of the power transformer 197 are each designed as planar conductor tracks, which are arranged in different positions on the printed circuit board 75. The printed circuit board has a thermal connection with the cooling unit 22.

The thermal connection with the cooling unit 22 can have a thermally conductive leveling layer, which is firmly connected with its first surface to the first surface of the printed circuit board 75, and a connecting layer, which is firmly connected with its first surface to the second surface of the thermally conductive leveling layer and with its second surface to the heat distributor.

FIG. 11 shows how a control connection 128 of a semiconductor component can be contacted from the outside in a third power electronics component 188, 118 with cooling of the semiconductor components on both sides. In the embodiment shown in FIG. 11, the control connection 128 of the semiconductor device is electrically contacted from the upper surface of the third power electronics component 118. The bare die layer 14 can be seen in FIG. 11. The first substrate 6 with its two metallizations 9 and 11 and the first heat sink 5 are arranged on the lower surface of the bare die layer 14. The second substrate 18 with its metallizations 17 and 19 and the second heat sink 26 are mounted on the upper surface of the bare die layer 14. Furthermore, in FIG. 11, the additional substrate 102, which is provided with metallization layers 104 and 106 on both sides, is attached to the lower surface of the first heat sink 5. The additional substrate 120, which has the metallizations 122 and 124, is arranged on the upper surface of the second heat sink 26.

For electrical contacting of the control connection 128, a hole 130 is provided, which extends from the upper surface of the third power electronics component 118 through the second heat sink 26 to the control connection 128. A pin 132 made of conductive material, preferably copper or another metal, is inserted into the hole 130 such that the pin 130 electrically contacts the control connection 128. In this way, a via is formed that leads the control connection 128 through the second heat sink 26 to the outside. Optionally, a connection surface 134 can be provided on the upper surface of the power electronics component above the additional substrate 120, the connection surface 134 being electrically connected to the control connection 128 via the pin 132.

In the area of the second heat sink 26, via insulation 116 can be provided, which protects the through-connection from electrical contact with the second heat sink 26.

The features disclosed in the above description and the drawings can be important both individually and in any combination for implementing the various configurations of the development described herein.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power electronics component, comprising:
a first electrically insulating substrate with an upper surface and a lower surface, the first electrically insulating substrate having an upper surface metallization layer on the upper surface and a lower surface metallization layer on the lower surface;
a semiconductor assembly mounted on the first electrically insulating substrate and having at least one first connection thermally and electrically connected to at least one first region of the upper surface metallization layer of the first electrically insulating substrate, wherein the upper surface metallization layer of the first electrically insulating substrate faces the semiconductor assembly;
a second electrically insulating substrate with an upper surface and a lower surface mounted on the semiconductor assembly and having an upper surface metallization layer on the upper surface of the second electrically insulating substrate and a lower metallization layer on the lower surface of the second electrically insulating substrate, wherein the semiconductor assembly has at least one second connection thermally and electrically connected to at least one second region of the lower surface metallization layer of the second electrically insulating substrate, and wherein the lower surface metallization layer of the second electrically insulating substrate faces the semiconductor assembly;
a first heat sink thermally connected to the lower surface metallization layer of the first electrically insulating substrate, the lower surface metallization layer of the first electrically insulating substrate facing away from the semiconductor assembly, the first heat sink having at least one first cooling channel through which coolant is configured to flow;
a second heat sink thermally connected to the upper surface metallization layer of the second electrically insulating substrate, the upper surface metallization layer of the second electrically insulating substrate facing away from the semiconductor assembly, the second heat sink having at least one second cooling channel through which coolant is configured to flow.

2. The power electronics component according to claim 1, wherein the second heat sink is at least partially in a form of a layered structure made of thermally bonded metal foils.

3. The power electronics component according to claim 1, wherein the first electrically insulating substrate and/or the second electrically insulating substrate is one of the following: ceramic substrate, direct bonded copper, insulated metal substrate, active metal brazed, or thick film substrate.

4. The power electronics component according to claim 1, further comprising:
an additional electrically insulating substrate with an upper surface and a lower surface, the additional electrically insulating substrate having a an upper surface metallization layer on the upper surface of the additional electrically insulating substrate and a lower surface metallization layer on the lower surface of the additional electrically insulating substrate, wherein the additional electrically insulating substrate is mounted on a second side of the first heat sink opposite a first side of the first heat sink, and wherein the second side of the first heat sink is thermally connected to the upper surface metallization layer of the additional electrically insulating substrate, the upper surface metallization layer of the additional electrically insulating substrate facing the first heat sink.

5. The power electronics component according to claim 4, further comprising control electronics arranged on a side of the additional electrically insulating substrate facing away from the first heat sink, wherein at least one connection of the control electronics is thermally and electrically connected to at least one region of the lower surface metallization layer of the additional electrically insulating substrate, the lower surface metallization layer of the additional electrically insulating substrate facing the control electronics.

6. The power electronics component according to claim 5, wherein at least one further connection of the control electronics is electrically connected to a connection of the semiconductor assembly by at least one via which passes through the first heat sink.

7. The power electronics component according to claim 4, wherein the first electrically insulating substrate and/or the additional electrically insulating substrate is one of the following: ceramic substrate, direct bonded copper, insulated metal substrate, active metal brazed, or thick film substrate.

8. The power electronics component according to claim 1, wherein the semiconductor assembly has a bare die layer, wherein the bare die layer comprises a semiconductor device.

9. The power electronics component according to claim 1, wherein the first heat sink is at least partially in a form of a layered structure made of thermally bonded metal foils.

10. The power electronics component according to claim 9, wherein the at least one first cooling channel is in a form of at least one recess provided in the thermally bonded metal foils.

11. The power electronics component according to claim 1, wherein the first heat sink is formed least partially by additive manufacturing.

12. The power electronics component according to claim 1, wherein the first heat sink comprises a coolant inlet and a coolant outlet, both of which are fluidically connected to the at least one first cooling channel, wherein the first heat sink is configured such that the first heat sink can be detachably mounted on a cooler comprising a first fluid port and a second fluid port, and wherein a first fluidic connection is configured to be formed between the coolant inlet of the first heat sink and the first fluid port of the cooler based on the first heat sink being mounted on the cooler, and a second fluidic connection is configured to be formed between the coolant outlet of the first heat sink and the second fluid port of the cooler.

13. The power electronics component according to claim 1, wherein the first electrically insulating substrate is materially bonded to the first heat sink on a first cooling wall,
wherein the power electronics component is configured such that, during operation, the coolant is guided through the at least one first cooling channel at a predetermined operating pressure of 3 or more bar overpressure relative to ambient pressure,
wherein a distance between the at least one first cooling channel and the first cooling wall is configured to be so small that the first heat sink, without the first electrically insulating substrate being materially bonded thereto, does not provide sufficient structural stability and/or tightness at a specified operating pressure, and
wherein the first electrically insulating substrate and its materially bonded connection with the first heat sink on the first cooling wall is configured such that the power electronics component provides sufficient structural stability and/or tightness at the specified operating pressure.

14. The component according to claim 1, wherein at least one control connection and at least one first power connection are arranged on a first side of the semiconductor assembly and at least one second power connection is arranged on a second side of the semiconductor assembly.

15. The component according to claim 14, wherein the upper surface metallization layer of the first electrically insulating substrate facing the first side of the semiconductor assembly has at least one first metallization region for electrically contacting at least one control connection of the semiconductor assembly and at least one second metallization region for electrically contacting at least one first power connection of the semiconductor assembly, wherein the at least one first metallization region and the at least one second metallization region are electrically separated from each other, and wherein the at least one first metallization region extends towards a side of the power electronics component and is configured to be electrically contacted from the side of the power electronics component.

16. The component according to claim 1, wherein electrical contacting of the at least one control connection of the semiconductor assembly is configured to be carried out by at least one via that extends through the first heat sink.

17. A method for joining a power electronics component, the method comprising:
arranging a semiconductor assembly on a first electrically insulating substrate having an upper surface and a lower surface, the first electrically insulating substrate having an upper surface metallization layer on the upper surface and a lower surface metallization layer on the lower surface;
establishing at least one thermal and electrical connection between at least one first connection of the semiconductor assembly and at least one first region of the upper surface metallization layer of the first electrically insulating substrate, the upper surface metallization layer of the first electrically insulating substrate facing the semiconductor assembly;
arranging a second electrically insulating substrate on the semiconductor assembly, wherein the second electrically insulating substrate has an upper surface and a lower surface, and wherein the second electrically insulating substrate has an upper surface metallization layer on the upper surface of the second electrically insulating substrate and a lower surface metallization layer on the lower surface of the second electrically insulating substrate;
establishing at least one thermal and electrical connection between at least one second connection of the semiconductor assembly and at least one second region of the lower surface metallization layer of the second electrically insulating substrate, the lower surface metallization layer of the second electrically insulating substrate facing the semiconductor assembly;
arranging a first heat sink on the first electrically insulating substrate, wherein the first heat sink has at least one first cooling channel through which coolant is configured to flow;
establishing a thermal and electrical connection between the first heat sink and the lower surface metallization layer of the first electrically insulating substrate, the lower surface metallization layer of the first electrically insulating substrate facing away from the semiconductor assembly;
arranging a second heat sink on the second electrically insulating substrate, wherein the second heat sink has at least one second cooling channel through which coolant is configured to flow; and
establishing a thermal and electrical connection between the second heat sink and the upper surface metallization layer of the second electrically insulating substrate, the upper surface metallization layer of the second electrically insulating substrate facing away from the semiconductor assembly.

18. The method according to claim 17, wherein the second heat sink is manufactured at least partially by direct copper bonding.

19. The method according to claim 18, wherein the upper surface and lower surface metallization layers of the second electrically insulating substrate and metal foils of the second heat sink are connected in a connecting process.

20. The method according to claim 17, further comprising:
arranging an additional electrically insulating substrate on a second side of the first heat sink opposite a first side of the first heat sink, wherein the additional electrically insulating substrate has an upper surface and a lower surface, and wherein the additional electrically insulating substrate has an upper surface metallization layer on the upper surface of the additional electrically insulating substrate and a lower surface metallization layer on the lower surface of the additional electrically insulating substrate; and
establishing a thermal and electrical connection between the second side of the first heat sink and the upper surface metallization layer of the additional electrically insulating substrate, the upper surface metallization layer of the additional electrically insulating substrate facing the first heat sink.

21. The method according to claim 17, wherein the first heat sink is manufactured at least partially by direct copper bonding.

22. The method according to claim 17, wherein the upper and lower surface metallization layers of the first electrically insulating substrate and metal foils of the first heat sink are joined in a joining process.

23. An electrical power converter for an industrial process assembly, comprising:
the power electronics component according to claim 1, wherein the power electronics component is configured to generate a high-frequency output power.

24. The electrical power converter according to claim 23, wherein the power electronics component comprises:
two power transistors, each having a first and a second power connection and a control connection, wherein both transistors are connected with one of respective power connections of the first and second power connections in series, wherein a direct current or direct voltage is connected to respective remaining power connections of the first and second power connections, wherein control electronic are further provided, the control electronics being connected with the control connections of the two transistors, and the control electronics being configured to control the transistors such that the transistors generate a high-frequency power by switching from a first conductive state into a second conductive state, wherein a conductivity of the two states is different.

25. The electrical power converter according to claim 24, wherein the two transistors, are each connected with their respective first power connection to a common ground connection point, wherein the two transistors, are of a same design and are arranged on a multilayer printed circuit board.

26. The electrical power converter according to claim 24, wherein one of the two transistors, is connected with its first power connection to the other transistor and with its second power connection to a common connection point, wherein the two transistors, are of a same design and are arranged on a multilayer printed circuit board.

27. The electrical power converter according to claim 24, wherein a power transformer with a primary winding and a secondary winding is arranged on a printed circuit board, wherein the primary winding is connected to at least one of the power connections of the transistors, wherein the primary winding and the secondary winding of the power transformer are each configured as planar conductor tracks which are arranged in different layers of the printed circuit board and wherein the printed circuit board has a thermal connection with a cooler.

28. The electrical power converter according to claim 27, wherein the thermal connection with the cooler has a thermally conductive leveling layer which is firmly connected with a first surface to a first surface of the printed circuit board, and wherein the thermal connection with the cooler has a connecting layer which is firmly connected with its first surface to a second surface of the thermally conductive leveling layer and with its second surface to a heat distributor.
